(19) United States
(12) Patent Application Publication
(10) Pub. No.: US 2026/0198214 A1
(43) Pub. Date: Jul. 9, 2026

(54) DISPLAY DEVICE, METHOD OF MANUFACTURING THE SAME, AND ELECTRONIC DEVICE INCLUDING THE DISPLAY DEVICE

(71) Applicant: Samsung Display Co., Ltd., Yongin-Si (KR)

(72) Inventors: SUK WON JUNG, Yongin-si (KR); Jaehyun Kim, Yongin-si (KR); JUNEHYOUNG PARK, Yongin-si (KR); SANG-CHUL BYUN, Yongin-si (KR); HUI YEON SHON, Yongin-si (KR); HYUN JOON OH, Yongin-si (KR)

(21) Appl. No.: 19/409,081

(22) Filed: Dec. 4, 2025

(30) Foreign Application Priority Data
Jan. 7, 2025 (KR) 10-2025-0002302

(51) Int. Cl. H10K 59/80

(52) U.S. Cl. CPC H10K 59/8792; H10K 59/873

(57) ABSTRACT

A display device includes a display panel including a display area and a peripheral area surrounding the display area, a protective film layer on the display panel, a polarizing layer on the protective film layer, an adhesive layer including a first adhesive layer between the display panel and the protective film layer and a second adhesive layer between the protective film layer and the polarizing layer, and a light-shielding member on at least one of opposite surfaces of the protective film layer.

### CROSS-REFERENCE TO RELATED APPLICATION

This application is based on and claims priority under 35 U.S.C. §119 to Korean Patent Application No. 10-2025-0002302, filed on January 7, 2025, in the Korean Intellectual Property Office, the disclosure of which is incorporated by reference herein in its entirety.

### BACKGROUND

### 1. Field

The present disclosure relates to a display device, a method of manufacturing the same, and an electronic device including the display device.

### 2. Description of the Related Art

With the increasing demand for display devices, the need for display devices that may be used for various purposes is also increasing. In line with this trend, display devices are becoming increasingly larger and thinner, and the need for larger and thinner display devices that provide accurate and vivid colors is also increasing.

### SUMMARY

Embodiments of the present disclosure may provide a display device with improved stability and optical characteristics, a method of manufacturing the display device, and an electronic device including the display device.

However, these aspects are exemplary and the tasks to be solved by the present disclosure are not limited thereto.

An embodiment of an electronic device includes a display device divided into a display area, in which a pixel circuit is arranged, and a peripheral area, which is outside the display area and includes a pad area, wherein the display device includes a display panel including the display area and the peripheral area surrounding the display area; a protective film layer on the display panel; a polarizing layer on the protective film layer; an adhesive layer including a first adhesive layer between the display panel and the protective film layer and a second adhesive layer between the protective film layer and the polarizing layer; a light-shielding member on at least one of opposite surfaces of the protective film layer; and a housing covering at least a portion of an outer perimeter of the display panel.

In an embodiment, a storage modulus of the first adhesive layer may be greater than a storage modulus of the second adhesive layer.

In an embodiment, the housing may overlap at least a portion of each of a side surface and a top surface of the second adhesive layer.

In an embodiment, the housing may be in contact with at least a portion of a side surface of the polarizing layer.

In an embodiment, the electronic device may further include a sealing portion between the display panel and the housing.

In an embodiment, the protective film layer may include an organic material.

In an embodiment, the display panel may include a substrate, a pixel layer on the substrate, and an encapsulation member on the pixel layer.

In an embodiment, the polarizing layer may include a hard coating layer in an outermost part of the display device.

An embodiment of a display device includes a display panel including a display area and a peripheral area surrounding the display area; a protective film layer on the display panel; a polarizing layer on the protective film layer; an adhesive layer including a first adhesive layer between the display panel and the protective film layer and a second adhesive layer between the protective film layer and the polarizing layer; and a light-shielding member on at least one of opposite surfaces of the protective film layer.

In an embodiment, the light-shielding member may be arranged between the protective film layer and the polarizing layer and between the protective film layer and the display panel.

In an embodiment, the light-shielding member may be arranged inside the adhesive layer.

In an embodiment, the light-shielding member may be arranged inside the protective film layer.

In an embodiment, the light-shielding member may have a thickness less than half a thickness of the first adhesive layer or the second adhesive layer.

In an embodiment, the light-shielding member may overlap the peripheral area.

In an embodiment, the first adhesive layer and the second adhesive layer may have different storage moduli from each other.

In an embodiment, the storage modulus of the first adhesive layer may be greater than the storage modulus of the second adhesive layer.

In an embodiment, when the polarizing layer shrinks, a surface of the second adhesive layer in contact with the polarizing layer may shrink in a shrinkage direction of the polarizing layer.

In an embodiment, as viewed in a direction perpendicular to the display panel, the polarizing layer may be spaced apart inward from an edge of the protective film layer.

In an embodiment, the protective film layer may include an organic material.

In an embodiment, the display panel may further include a substrate, a pixel layer on the substrate, and an encapsulation member on the pixel layer.

In an embodiment, the polarizing layer may include a hard coating layer in an outermost part of the display device.

An embodiment of a display device includes a display panel including a substrate; a protective film layer on the display panel; a polarizing layer on the protective film layer; an adhesive layer including a first adhesive layer between the display panel and the protective film layer and a second adhesive layer between the protective film layer and the polarizing layer; and a light-shielding member on at least one of opposite surfaces of the protective film layer, wherein the polarizing layer is arranged in an outermost part of the display device and does not have an upper substrate on the polarizing layer.

In an embodiment, a storage modulus of the first adhesive layer may be greater than a storage modulus of the second adhesive layer.

In an embodiment, when the polarizing layer shrinks, a surface of the second adhesive layer in contact with the polarizing layer may shrink in a shrinkage direction of the polarizing layer.

In an embodiment, as viewed in a direction perpendicular to the display panel, the polarizing layer may be spaced apart inward from an edge of the protective film layer.

In an embodiment, the display device may further include a light-shielding member arranged in at least one of locations between the protective film layer and the polarizing layer and between the protective film layer and the display panel.

In an embodiment, the light-shielding member may be arranged inside the adhesive layer.

In an embodiment, the light-shielding member may be arranged inside the protective film layer.

In an embodiment, the light-shielding member may have a thickness less than half a thickness of the first adhesive layer or the second adhesive layer.

In an embodiment, the light-shielding member may be arranged along an edge of the protective film layer.

In an embodiment, the protective film layer may include an organic material.

In an embodiment, the display panel may further include a pixel layer on the substrate and an encapsulation member on the pixel layer.

In an embodiment, the polarizing layer may include a hard coating layer disposed in the outermost part of the display device.

An embodiment of a method of manufacturing a display device includes preparing a protective film layer; arranging a light-shielding member on at least one surface of the protective film layer; and arranging a polarizing layer on a surface of the protective film layer, on which the light-shielding member is arranged, and a display panel on an another surface of the protective film layer.

In an embodiment, the arranging of the light-shielding member may include positioning the light-shielding member on the at least one surface of the protective film layer; pressurizing the light-shielding member; and curing the pressurized light-shielding member.

In an embodiment, the method may further include laminating an adhesive layer to opposite surfaces of the protective film layer.

In an embodiment, the laminating of the adhesive layer to the opposite surfaces of the protective film layer may include laminating a first adhesive layer to one of the opposite surfaces of the protective film layer and laminating a second adhesive layer to the other one of the opposite surfaces of the protective film layer, the second adhesive layer having a storage modulus different from a storage modulus of the first adhesive layer.

In an embodiment, the storage modulus of the first adhesive layer may be greater than the storage modulus of the second adhesive layer.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view schematically illustrating a display device according to an embodiment of the present disclosure;

FIG. 2 is a cross-sectional view schematically illustrating an example of a cross-section along line I-I' in FIG. 1;

FIG. 3 is a plan view schematically illustrating a part of the display device of FIG. 1;

FIG. 4 is a circuit diagram illustrating an example of a pixel of the display device of FIG. 1;

FIG. 5 is a cross-sectional view schematically illustrating an example of a cross-section of a pixel in FIG. 3;

FIG. 6 is a schematic cross-sectional view taken along line I-I' in FIG. 1, according to an embodiment;

FIG. 7 is a schematic cross-sectional view taken along line I-I' in FIG. 1, according to an embodiment;

FIGS. 8 and 9 are diagrams illustrating an example of a force acting on a polarizing layer;

FIG. 10 is a schematic cross-sectional view taken along line I-I' in FIG. 1, according to an embodiment;

FIG. 11 is an enlarged view of a region X in FIG. 10;

FIG. 12 is a schematic cross-sectional view taken along line I-I' in FIG. 1, according to an embodiment;

FIG. 13 is an enlarged view of a region Y in FIG. 12;

FIG. 14 is a schematic cross-sectional view taken along line I-I' in FIG. 1, according to an embodiment;

FIG. 15 is an enlarged view of a region Z in FIG. 14;

FIG. 16 is a schematic cross-sectional view taken along line I-I' in FIG. 1, according to an embodiment;

FIG. 17 is an enlarged view of a region X' in FIG. 16;

FIG. 18 is a schematic cross-sectional view taken along line I-I' in FIG. 1, according to an embodiment;

FIG. 19 is a schematic cross-sectional view taken along line I-I' in FIG. 1, according to an embodiment;

FIG. 20 is a schematic cross-sectional view taken along line I-I' in FIG. 1, according to an embodiment;

FIGS. 21 and 22 are schematic flowcharts of a method of manufacturing a display device, according to an embodiment of the present disclosure;

FIGS. 23, 24, 25, and 26 are diagrams schematically illustrating a method of manufacturing a display device, according to an embodiment of the present disclosure; and

FIG. 27 is a block diagram schematically illustrating an example of an electronic device according to embodiments of the present disclosure.

### DETAILED DESCRIPTION

Embodiments of the present disclosure may undergo various modifications and have various embodiments, and specific embodiments are illustrated in the drawings and described in detail in the detailed description. The effects and features of the present disclosure and the method for achieving them will become clear with reference to the embodiments described in detail below together with the drawings. However, the present disclosure is not limited to the embodiments disclosed below and may be implemented in various forms.

As used herein, the terms "first," "second, etc. are not used in a limiting sense but are used to distinguish one component from another.

As used herein, singular expressions include plural expressions unless the context clearly indicates otherwise.

As used herein, the terms “comprise,” “include,” and “have” (as well as their variations such as “comprising”) specify the presence of stated features or components, but do not preclude the presence or addition of one or more other features or components.

As used herein, when it is said that a part, such as a unit, region, or component, is located above or on another part, this includes not only the case where it is directly above the other part but also the case where another unit, region, component, etc. is interposed in between.

As used herein, terms, such as "connect" or "combine", do not necessarily imply a direct and/or fixed connection or combination of two members, unless the context clearly indicates otherwise, and do not exclude the presence of another member between the two members.

In the drawings, the sizes of components may be exaggerated or reduced for convenience of explanation. For example, the sizes and/or thicknesses of components in the drawings are arbitrarily shown for convenience of explanation, and therefore, the present disclosure is not necessarily limited thereto.

Hereinafter, embodiments of the present disclosure will be described in detail with reference to the attached drawings. In the drawings, identical or corresponding components are given the same reference numerals, and redundant descriptions thereof will be omitted.

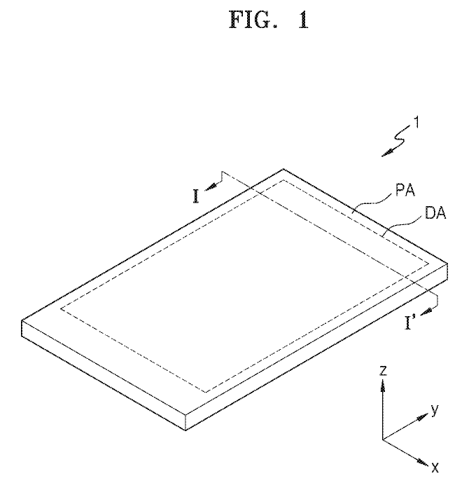

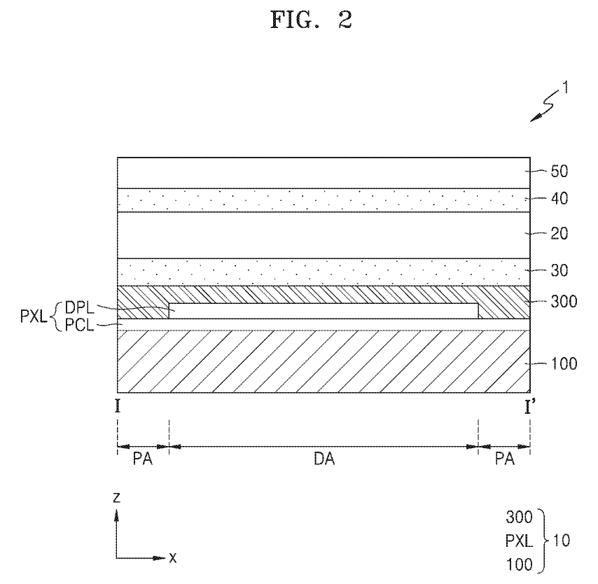

FIG. 1 is a perspective view schematically illustrating a display device according to an embodiment of the present disclosure. FIG. 2 is a cross-sectional view schematically illustrating an example of a cross-section along line I-I' in FIG. 1.

Referring to FIG. 1, according to an embodiment of the present disclosure, a display device 1 may include a display area DA and a peripheral area PA. The peripheral area PA may be arranged at an outer side of the display area DA to surround the display area DA. A driver circuit and various wirings that transmit electrical signals to be applied to the display area DA may be located in the peripheral area PA. The display device 1 may provide a certain image by using light emitted from a plurality of pixels arranged in the display area DA. Although not shown, the display device 1 may be bent by including a bending region in a portion of the peripheral area PA.

The display device 1 may include an organic light emitting display device, an inorganic light emitting display device (or inorganic electroluminescence (EL) display device), or a quantum dot light emitting display device. Hereinafter, an organic light emitting display device will be used as an example. The display device 1 may be implemented in various types of electronic devices, such as a mobile phone, a laptop computer, and a smart watch.

As shown in FIG. 2, the display device 1 may include a display panel 10, a protective film layer 20 on the display panel 10, and a polarizing layer 50 on the protective film layer 20, wherein the display panel 10, the protective film layer 20, and the polarizing layer 50 are sequentially stacked in the thickness direction (the z-direction). Specifically, the display panel 10 may include a substrate 100, a pixel layer PXL on the substrate 100, and a encapsulation member 300 disposed on the pixel layer PXL to seal the pixel layer PXL, wherein the substrate 100, the pixel layer PXL, and the encapsulation member 300 are sequentially stacked in the thickness direction (the z-direction). The display device 1 may also include a first adhesive layer 30 between the encapsulation member 300 and the protective film layer 20 and a second adhesive layer 40 between the protective film layer 20 and the polarizing layer 50.

The substrate 100 may include a glass material or a polymer resin. For example, the substrate 100 may include a glass material containing SiO2 as a main component or may include various materials, which have a flexible or bendable characteristic, for example, resin such as reinforced plastic. Although not shown, the substrate 100 may be bent by including a bending region in a portion of the peripheral area PA.

The pixel layer PXL may be arranged on the substrate 100. The pixel layer PXL may include a display element layer DPL, which includes display elements arranged for pixels, and a pixel circuit layer PCL, which includes pixel circuits and insulating layers arranged for the pixels. The display element layer DPL may be arranged on the top of the pixel circuit layer PCL, and a plurality of insulating layers may be arranged between a pixel circuit and a display element. Some wirings and insulating layers of the pixel circuit layer PCL may extend to the peripheral area PA.

The encapsulation member 300 may include a thin-film encapsulation layer. The thin-film encapsulation layer may include at least one inorganic encapsulation layer and at least one organic encapsulation layer. When the display device 1 includes the substrate 100 including polymer resin and the encapsulation member 300 including a thin-film encapsulation layer including an inorganic encapsulation layer and an organic encapsulation layer, the flexibility of the display device 1 may be increased.

The protective film layer 20 may protect the display device 1. For example, the protective film layer 20 may protect the display device 1 from external impact on the display device 1.

The polarizing layer 50 may transmit only light, which vibrates in the same direction as the polarization axis among the light emitted from a display element of the display element layer DPL, and may absorb or reflect light vibrating in the other directions.

The first adhesive layer 30 may be between the encapsulation member 300 and the protective film layer 20 to bond the encapsulation member 300 to the protective film layer 20. The second adhesive layer 40 may be between the protective film layer 20 and the polarizing layer 50 to bond the protective film layer 20 to the polarizing layer 50.

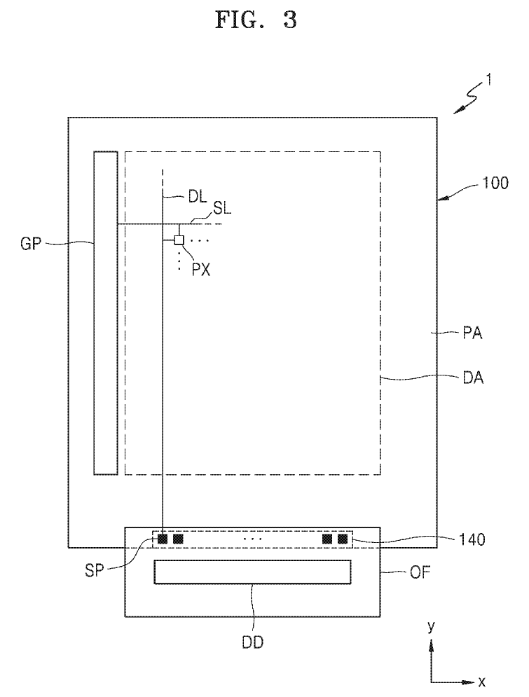

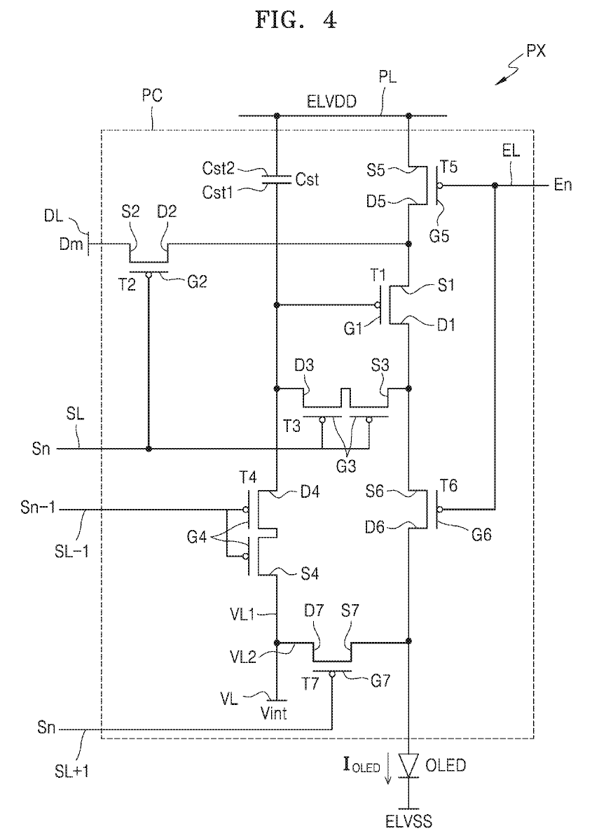

FIG. 3 is a plan view schematically illustrating a part of the display device 1 of FIG. 1. FIG. 4 is a circuit diagram illustrating an example of a pixel of the display device 1 of FIG. 1. Referring to FIG. 3, the substrate 100 may include a display area DA and a peripheral area PA. The peripheral area PA may be at an outer side of the display area DA and may surround the display area DA.

The display area DA on the top of the substrate 100 may be provided with a plurality of pixels PX arranged in a certain pattern in a first direction (the x-direction or the row direction) and a second direction (the y-direction or the column direction).

A scan driver GP that provides a scan signal to each pixel PX, a data driver DD that provides a data signal to each pixel PX, and main power lines (not shown) for providing a first power supply voltage (e.g., ELVDD in FIG. 4) and a second power supply voltage (e.g., ELVSS in FIG. 4) may be arranged in the peripheral area PA on the top of the substrate 100. A pad unit 140 in which a plurality of signal pads SP connected to a data line DL are arranged may be located in the peripheral area PA on the top of the substrate 100.

The scan driver GP may include an oxide semiconductor thin-film transistor (TFT) gate driver circuit (OSG) or an amorphous silicon TFT gate driver circuit (ASG). Although FIG. 3 illustrates that the scan driver GP is adjacent to one side of the substrate 100, the scan driver GP may be adjacent to each of two facing sides of the substrate 100, according to an embodiment.

FIG. 3 illustrates a chip-on-film (COF) manner, in which the data driver DD is on a film OF electrically connected to the signal pads SP arranged on the top of the substrate 100. According to other embodiments, the data driver DD may be directly arranged on the top of the substrate 100 in a chip-on-glass (COG) manner or a chip-on-plastic (COP) manner. The data driver DD may be electrically connected to a flexible printed circuit board (FPCB).

Referring to FIG. 4, one pixel PX may include a pixel circuit PC and an organic light-emitting device OLED electrically connected to the pixel circuit PC.

Each pixel PX may emit light, e.g., red light, green light, blue light, or white light, via the organic light-emitting device OLED.

The pixel circuit PC may include a plurality of transistors (e.g., T1 to T7) and a storage capacitor Cst, as shown in FIG. 4. The transistors (T1 to T7) and the storage capacitor Cst may be connected to signal lines (e.g., SL, SL-1, SL+1, EL, and DL), a first initialization voltage line VL1, a second initialization voltage line VL2, and a driving voltage line PL.

The signal lines (SL, SL-1, SL+1, EL, and DL) may include a scan line SL transmitting a scan signal Sn, a previous scan line SL-1 transmitting a previous scan signal Sn-1 to a first initialization transistor T4, a subsequent scan line SL+1 transmitting the scan signal Sn to a second initialization transistor T7, a light emission control line EL transmitting a light emission control signal En to an operation control transistor T5 and a light emission control transistor T6, and a data line DL intersecting the scan line SL and transmitting a data signal Dm. The driving voltage line PL may transmit a driving voltage ELVDD to a driving transistor T1. The first initialization voltage line VL1 may transmit an initialization voltage Vint to the first initialization transistor T4. The second initialization voltage line VL2 may transmit the initialization voltage Vint to the second initialization transistor T7.

A driving gate electrode G1 of the driving transistor T1 may be connected to a lower electrode CE1 of the storage capacitor Cst, a driving source electrode S1 of the driving transistor T1 may be connected to the driving voltage line PL via the operation control transistor T5, and a driving drain electrode D1 of the driving transistor T1 may be electrically connected to a pixel electrode of the organic light-emitting device OLED via the light emission control transistor T6. The driving transistor T1 may receive the data signal Dm according to the switching operation of a switching transistor T2 and may supply a driving current I_{OLED} to the organic light-emitting device OLED.

A switching gate electrode G2 of the switching transistor T2 may be connected to the scan line SL, a switching source electrode S2 of the switching transistor T2 may be connected to the data line DL, and a switching drain electrode D2 of the switching transistor T2 may be connected to the driving source electrode S1 of the driving transistor T1 and to the driving voltage line PL via the operation control transistor T5. The switching transistor T2 may be turned on according to the scan signal Sn received through the scan line SL and may perform a switching operation to transmit the data signal Dm transmitted through the data line DL to the driving source electrode S1 of the driving transistor T1.

A compensation gate electrode G3 of a compensation transistor T3 may be connected to the scan line SL, a compensation source electrode S3 of the compensation transistor T3 may be connected to the driving drain electrode D1 of the driving transistor T1 and to the pixel electrode of the organic light-emitting device OLED via the light emission control transistor T6, and a compensation drain electrode D3 of the compensation transistor T3 may be connected to the lower electrode CE1 of the storage capacitor Cst, a first initialization drain electrode D4 of the first initialization transistor T4, and the driving gate electrode G1 of the driving transistor T1. The compensation transistor T3 may be turned on according to the scan signal Sn received through the scan line SL and may electrically connect the driving gate electrode G1 and the driving drain electrode D1 of the driving transistor T1 to each other, thereby creating diode-connection of the driving transistor T1.

A first initialization gate electrode G4 of the first initialization transistor T4 may be connected to the previous scan line SL-1, a first initialization source electrode S4 of the first initialization transistor T4 may be connected to the first initialization voltage line VL1, and the first initialization drain electrode D4 of the first initialization transistor T4 may be connected to the lower electrode CE1 of the storage capacitor Cst, the compensation drain electrode D3 of the compensation transistor T3, and the driving gate electrode G1 of the driving transistor T1. The first initialization transistor T4 may be turned on according to the previous scan signal Sn-1 received through the previous scan line SL-1 and performs an initialization operation to initialize the voltage of the driving gate electrode G1 of the driving transistor T1 by transmitting the initialization voltage Vint to the driving gate electrode G1 of the driving transistor T1.

An operation control gate electrode G5 of the operation control transistor T5 may be connected to the light emission control line EL, an operation control source electrode S5 of the operation control transistor T5 may be connected to the driving voltage line PL, and an operation control drain electrode D5 of the operation control transistor T5 may be connected to the driving source electrode S1 of the driving transistor T1 and the switching drain electrode D2 of the switching transistor T2.

A light emission control gate electrode G6 of the light emission control transistor T6 may be connected to the light emission control line EL, a light emission control source electrode S6 of the light emission control transistor T6 may be connected to the driving drain electrode D1 of the driving transistor T1 and the compensation source electrode S3 of the compensation transistor T3, and a light emission control drain electrode D6 of the light emission control transistor T6 may be electrically connected to a second initialization source electrode S7 of the second initialization transistor T7 and the pixel electrode of the organic light-emitting device OLED.

The operation control transistor T5 and the light emission control transistor T6 may be simultaneously turned on according to the light emission control signal En received through the light emission control line EL so that the driving voltage ELVDD may be transmitted to the organic light-emitting device OLED, and thus, the driving current I_{OLED} may flow in the organic light-emitting device OLED.

A second initialization gate electrode G7 of the second initialization transistor T7 may be connected to the subsequent scan line SL+1, the second initialization source electrode S7 of the second initialization transistor T7 may be connected to the light emission control drain electrode D6 of the light emission control transistor T6 and the pixel electrode of the organic light-emitting device OLED, and a second initialization drain electrode D7 of the second initialization transistor T7 may be connected to the second initialization voltage line VL2.

Because the scan line SL is electrically connected to the subsequent scan line SL+1, the same scan signal Sn may be applied to the scan line SL and the subsequent scan line SL+1. Accordingly, the second initialization transistor T7 may be turned on according to the scan signal Sn received through the subsequent scan line SL+1 and may perform an operation of initializing the pixel electrode of the organic light-emitting device OLED.

An upper electrode CE2 of the storage capacitor Cst may be connected to the driving voltage line PL, and a common electrode of the organic light-emitting device OLED may be connected to a common voltage ELVSS. Accordingly, the organic light-emitting device OLED may display an image by receiving the driving current I_{OLED} from the driving transistor T1 and emitting light.

Although it is illustrated in FIG. 4 that the compensation transistor T3 and the first initialization transistor T4 each have a dual-gate electrode, the compensation transistor T3 and the first initialization transistor T4 may each have a single-gate electrode.

Although the structure of one pixel circuit PC is described with reference to FIG. 4, a plurality of pixels PX each having the same pixel circuit PC may be arranged to form a plurality of rows. At this time, the first initialization voltage line VL1, the previous scan line SL-1, the second initialization voltage line VL2, and the subsequent scan line SL+1 may be shared by neighboring pixels.

For example, the first initialization voltage line VL1 and the previous scan line SL-1 of one pixel circuit PC may be electrically connected to a second initialization TFT of another pixel circuit PC arranged in the second direction (the y-direction). Accordingly, a previous scan signal applied to the previous scan line SL-1 may be transmitted as a subsequent scan signal to the second initialization TFT of the other pixel circuit PC. Similarly, the second initialization voltage line VL2 and the subsequent scan line SL+1 of one pixel circuit PC may be electrically connected to a first initialization TFT of another pixel circuit PC adjacent to the one pixel circuit PC in the second direction (the y-direction) and may thus transmit a previous scan signal and an initialization voltage to the first initialization TFT.

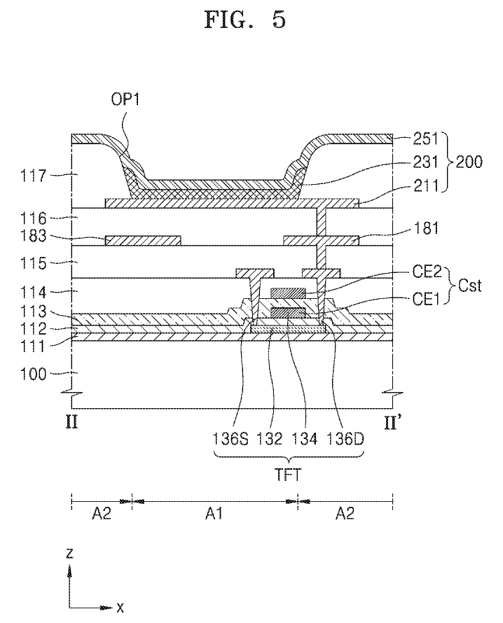

FIG. 5 is a cross-sectional view schematically illustrating an example of a cross-section of a pixel in FIG. 3.

Referring to FIG. 5, a buffer layer 111 may be formed on the substrate 100 to prevent impurities from penetrating into a semiconductor layer of a TFT.

The substrate 100 may include various materials, such as glass, metal, or plastic. According to an embodiment, the substrate 100 may include a flexible substrate, which may include polymer resin, such as polyethersulphone (PES), polyacrylate (PAR), polyetherimide (PEI), polyethyelenennapthalate (PEN), polyethyeleneterepthalate (PET), polyphenylenesulfide (PPS), polyallylate, polyimide (PI), polycarbonate (PC), or cellulose acetate propionate (CAP).

The buffer layer 111 may include an inorganic insulating material, such as silicon nitride or silicon oxide, and may include a single layer or multiple layers.

A thin-film transistor TFT, a capacitor Cst, and an organic light-emitting diode 200 electrically connected to the thin-film transistor TFT may be arranged on the substrate 100. The organic light-emitting diode 200 being electrically connected to the thin-film transistor TFT may be understood as a pixel electrode 211 being electrically connected to the thin-film transistor TFT. The thin-film transistor TFT may correspond to the driving transistor T1 in FIG. 4.

The thin-film transistor TFT may include a semiconductor layer 132, a gate electrode 134, a source electrode 136S, and a drain electrode 136D. The semiconductor layer 132 may include an oxide semiconductor material. The semiconductor layer 132 may include amorphous silicon, polycrystalline silicon, or an organic semiconductor material. The gate electrode 134 may be formed as a single layer or multiple layers by using one or more materials selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), taking into account adhesion to an adjacent layer, surface flatness of a layer and processability on which the gate electrode 134 is stacked, and/or the like.

A gate insulating layer 112, which includes an inorganic material, such as silicon oxide, silicon nitride, and/or silicon oxynitride, may be between the semiconductor layer 132 and the gate electrode 134. A first interlayer insulating layer 113 and a second interlayer insulating layer 114, each including an inorganic material, such as silicon oxide, silicon nitride, and/or silicon oxynitride, may be between the gate electrode 134 and each of the source electrode 136S and the drain electrode 136D. Each of the source electrode 136S and the drain electrode 136D may be electrically connected to the semiconductor layer 132 through contact holes respectively formed in the gate insulating layer 112, the first interlayer insulating layer 113, and the second interlayer insulating layer 114.

The source electrode 136S and the drain electrode 136D may be formed as a single layer or multiple layers by using one or more materials selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The capacitor Cst may include a lower electrode CE1 and an upper electrode CE2, which overlap each other with the first interlayer insulating layer 113 therebetween. The capacitor Cst may overlap the thin-film transistor TFT. In FIG. 5, the gate electrode 134 of the thin-film transistor TFT is illustrated as the lower electrode CE1 of the capacitor Cst. In an embodiment, the capacitor Cst may not overlap the thin-film transistor TFT. The capacitor Cst may be covered with the second interlayer insulating layer 114.

A pixel circuit including the thin-film transistor TFT and the capacitor Cst may be covered with a first insulating layer 115 and a second insulating layer 116. Each of the first insulating layer 115 and the second insulating layer 116 may be formed as a planarization insulating layer including an organic insulating layer. The first insulating layer 115 and the second insulating layer 116 may include an organic insulator, such as a general-purpose polymer, e.g., polymethylmethacrylate (PMMA) or polystylene (PS), a polymer derivative having a phenolic group, an acrylic polymer, an imide polymer, an aryl ether polymer, an amide polymer, a fluorinated polymer, a p-xylene polymer, a vinyl alcohol polymer, or a blend thereof. In an embodiment, the first insulating layer 115 and the second insulating layer 116 may include polyimide.

A display element, for example, the organic light-emitting diode 200, may be arranged on the second insulating layer 116. The organic light-emitting diode 200 may include the pixel electrode 211, an intermediate layer 231, and a counter electrode 251.

The pixel electrode 211 may be arranged on the second insulating layer 116 and connected to the thin-film transistor TFT through a connection electrode 181 on the first insulating layer 115. Wiring 183 including the data line DL and the driving voltage line PL may be arranged on the first insulating layer 115.

The pixel electrode 211 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the pixel electrode 211 may further include a film, which includes ITO, IZO, ZnO or In₂O₃, above/below the reflective film mentioned above.

A third insulating layer 117 may be arranged on the second insulating layer 116. The third insulating layer 117 may correspond to a pixel definition film that defines a pixel by covering the edge of the pixel electrode 211 and having a first opening OP1 exposing a portion of the pixel electrode 211. The first opening OP1 may correspond to a first area A1. The third insulating layer 117 may prevent arcs or the like from occurring at the edge of the pixel electrode 211 by increasing the distance between the edge of the pixel electrode 211 and the counter electrode 251. The third insulating layer 117 may include an organic material, such as polyimide (PI) or hexamethyldisiloxane (HMDSO).

The intermediate layer 231 may include a light-emitting layer. The light-emitting layer may include a polymer or small-molecule organic material, which emits light of a certain color. In an embodiment, the intermediate layer 231 may include a first functional layer below the light-emitting layer and/or a second functional layer above the light-emitting layer. The first functional layer and/or the second functional layer may include a layer that is integral across a plurality of pixel electrodes 211 or may include a layer patterned to correspond to each of the pixel electrodes 211.

The first functional layer may include a single layer or multiple layers. For example, when the first functional layer includes a polymer material, the first functional layer may correspond to a single-layer hole transport layer (HTL) and may include poly-(3,4)-ethylene-dihydroxy thiophene (PEDOT) or polyaniline (PANI). When the first functional layer includes a small-molecule material, the first functional layer may include a hole injection layer (HIL) and an HTL.

The second functional layer may not always be present. For example, when the first functional layer and the light-emitting layer include a polymer material, it may be preferable to form the second functional layer to improve the characteristics of an organic light-emitting diode. The second functional layer may include a single layer or multiple layers. The second functional layer may include an electron transport layer (ETL) and/or an electron injection layer (EIL).

The counter electrode 251 may face the pixel electrode 211 with the intermediate layer 231 between the counter electrode 251 and the pixel electrode 211. The counter electrode 251 may include a conductive material having a low work function. For example, the counter electrode 251 may include a transparent or semitransparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the counter electrode 251 may further include a layer, such as an ITO layer, an IZO layer, a ZnO layer, or In₂O₃ layer, on the transparent or semitransparent layer including the material mentioned above.

The counter electrode 251 may be arranged on the top of the intermediate layer 231 and the top of the third insulating layer 117. The counter electrode 251 may be integrally formed with respect to a plurality of organic light-emitting diodes 200 in the display area DA and may face a plurality of pixel electrodes 211.

A thin-film encapsulation layer may be arranged as the encapsulation member 300 on the top of the counter electrode 251. The thin-film encapsulation layer may protect the organic light-emitting diode 200 from external moisture or oxygen. The thin-film encapsulation layer may have a multi-layer structure. The thin-film encapsulation layer may include a first inorganic layer, an organic layer, and a second inorganic layer. By forming the thin-film encapsulation layer in a multi-layer structure, even if a crack occurs within the thin-film encapsulation layer, the crack may be prevented from continuing between the first inorganic layer and the organic layer or between the organic layer and the second inorganic layer. This may prevent or minimize the formation of a path through which external moisture or oxygen penetrates into the display area DA. In other embodiments, the number of organic layers, the number of inorganic layers, and the stacking order may be changed.

The first inorganic layer may cover the counter electrode 251 and may include one or more inorganic insulating materials selected from the group consisting of aluminum oxide, titanium oxide, tantalum oxide, hafnium oxide, zinc oxide, silicon oxide, silicon nitride, and silicon oxynitride. The first inorganic layer may be formed along the underlying structure thereof, and accordingly, the top surface of the first inorganic layer may not be flat.

The organic layer covers the first inorganic layer and can have a sufficient thickness. The upper surface of the organic layer can be substantially flat over the entire display area. The organic layer may include polyethylene terephthalate, polyethylene naphthalate, polycarbonate, polyimide, polyethylene sulfonate, polyoxymethylene, polyarylate, hexamethyldisiloxane, acrylic resin (e.g., polymethyl methacrylate, polyacrylic acid, etc.) or any combination thereof.

The second inorganic layer may cover the organic layer and may include one or more inorganic insulating materials selected from the group consisting of aluminum oxide, titanium oxide, tantalum oxide, hafnium oxide, zinc oxide, silicon oxide, silicon nitride, and silicon oxynitride. The second inorganic layer may extend outside the organic layer and contact the first inorganic layer in the peripheral area PA, thereby preventing the organic layer from being exposed to the outside.

In the process of forming the thin-film encapsulation layer, the underlying structures thereof may be damaged. For example, when the first inorganic layer is formed, a layer directly below the first inorganic layer may be damaged. Therefore, in order to prevent an underlying structure from being damaged in the process of forming the thin-film encapsulation layer, at least one capping layer and/or protective layer may be arranged between the counter electrode 251 and the thin-film encapsulation layer. The protective layer may include an inorganic material.

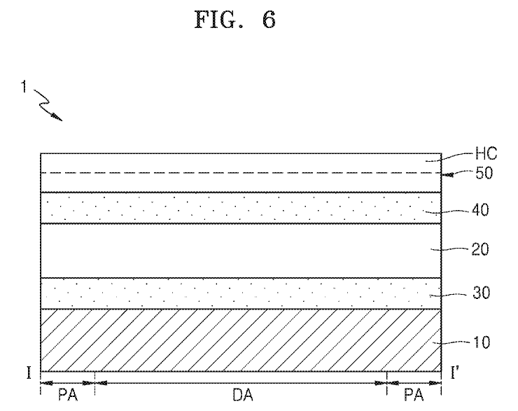

FIG. 6 is a schematic cross-sectional view taken along line I-I' in FIG. 1, according to an embodiment.

Referring to FIG. 6, according to an embodiment of the present disclosure, the display device 1 may include the display panel 10, the protective film layer 20, and the polarizing layer 50.

The display panel 10 may include a display area DA and a peripheral area PA. At this time, pixels PX may be arranged in the display area DA. The display panel 10 may provide an image by using light emitted from the pixels PX. Each of the pixels PX may emit light by using a display element. In an embodiment, the display element may correspond to the organic light-emitting device OLED. For example, each pixel PX may emit red, green, or blue light. For example, each pixel PX may emit red, green, blue, or white light.

In an embodiment, the display panel 10 may include at least one selected from the group consisting of the substrate 100, the organic light-emitting diode 200, and the encapsulation member 300, which have been described with reference to FIGS. 1 to 5. In a specific embodiment, the display panel 10 may include all of the substrate 100, the organic light-emitting diode 200, and the encapsulation member 300 described with reference to FIGS. 1 to 5. However, the display panel 10 is not limited thereto and may further include an additional component that performs another function. For example, the display panel 10 may further include various components to change the optical path of light or increase light extraction efficiency.

The protective film layer 20 may be arranged on the display panel 10.

The protective film layer 20 may be arranged on the display panel 10 to protect the display device 1 from external impact.

In an embodiment, the protective film layer 20 may include a protective film. The protective film may include various materials having satisfactory impact resistance and a flexible or bendable characteristic. For example, the protective film may include resin, such as plastic. In other words, the protective film layer 20 may include an organic material. For example, the protective film may include a urethane acrylate film containing urethane acrylate. Accordingly, the protective film layer 20 may be arranged on one side of the display panel 10 and may protect the display device 1 from external impact.

According to an embodiment of the present disclosure, the display device 1 may not include a window or cover glass (hereinafter collectively referred to as a window). Specifically, in the display device 1 according to the present embodiment, the protective film layer 20 provided as a film may functionally replace a window including a glass material. Accordingly, the display device 1 according to the present embodiment may have various superior effects compared to a case where a window including a glass material is provided. For example, the display device 1 according to the present embodiment may have a reduced thickness or weight.

The polarizing layer 50 may be arranged on the protective film layer 20. For example, the polarizing layer 50 may be arranged on a surface opposite to the display panel 10 with respect to the protective film layer 20. In other words, relative positional relations among the display panel 10, the protective film layer 20, and the polarizing layer 50 may be in the order of the display panel 10, the protective film layer 20, and the polarizing layer 50 based on FIG. 6.

The polarizing layer 50 may selectively transmit light emitted from a display element of the display element layer DPL. Specifically, the polarizing layer 50 may transmit only light, which vibrates in the same direction as the polarization axis among the light emitted from a display element of the display element layer DPL, and may absorb or reflect light vibrating in the other directions.

When the polarizing layer 50 is arranged as an outermost layer of the display device 1, and specifically, when the polarizing layer 50 is arranged as the uppermost layer of the display device 1 without an upper glass layer, such as a window or cover glass, thereon, the polarizing layer 50 may be composed of a high-hardness material.

The polarizing layer 50 may be arranged in an outermost part of the display device 1. An upper substrate including glass may not be provided on the polarizing layer 50 of the display device 1. In other words, an upper substrate layer including at least glass may not be arranged on the top of the polarizing layer 50. The upper substrate may refer to a layer containing glass. However, the upper substrate is not limited to a layer including at least glass and may be a layer identical or similar to the substrate 100.

The polarizing layer 50 having a high-hardness may further include a hard coating layer HC at the top of the polarizing layer 50 to protect the polarizing layer 50 from external impact. In other words, the hard coating layer HC may be arranged in the outermost part of the display device 1. The hard coating layer HC may have a scratch-resistant function and may have a hardness of about 9H.

The hard coating layer HC may include an organic material such as polymer resin. However, the present disclosure is not limited thereto. The hard coating layer HC may include an inorganic material.

The hard coating layer HC may be an outermost layer of the display device 1. The outermost layer may be a layer that users touch directly and may provide a smooth and soft touch to the users.

The polarizing layer 50 may be of a film type or a liquid crystal coating type but is not limited thereto.

According to an embodiment of the present disclosure, the display device 1 may include adhesive layers (e.g., 30 and 40).

The adhesive layers (30 and 40) may each be between several layers forming the display device 1 and may bond the layers to each other.

The adhesive layers (30 and 40) may each be between the display panel 10 and the protective film layer 20 or between the protective film layer 20 and the polarizing layer 50.

The adhesive layers (30 and 40) may include a bonding film. For example, the bonding film may include resin, such as acrylic, polyimide, or polycarbonate, which has light-transmitting properties.

In an embodiment, the adhesive layers (30 and 40) may include the first adhesive layer 30 and the second adhesive layer 40. The first adhesive layer 30 can be interposed between the display panel 10 and the protective film layer 20 and can perform the function of adhering the display panel 10 and the protective film layer 20. The second adhesive layer 40 may be between the protective film layer 20 and the polarizing layer 50 and may bond the protective film layer 20 to the polarizing layer 50.

In an embodiment, the first adhesive layer 30 and the second adhesive layer 40 may have different properties. For example, the first adhesive layer 30 and the second adhesive layer 40 may have different storage moduli. Accordingly, even when the display device 1 according to the present disclosure receives a force in a direction in which the display device 1 is unidirectionally bent, the force applied to the display device 1 may be compensated for by the first adhesive layer 30 and the second adhesive layer 40, which have different storage moduli.

This will be described in detail below.

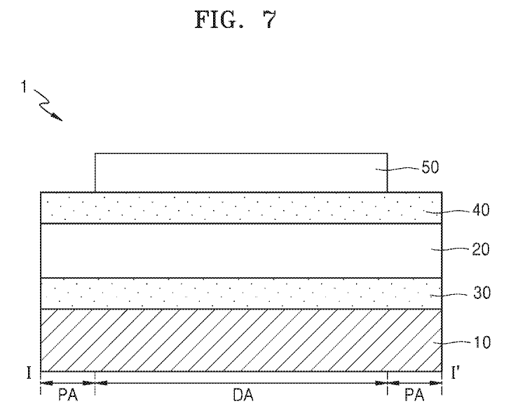

FIG. 7 is a schematic cross-sectional view taken along line I-I' in FIG. 1, according to another embodiment.

Referring to FIG. 7, as viewed in a direction perpendicular to the display panel 10 (in the z-direction in FIGS. 1 and 2), the polarizing layer 50 may be spaced apart inward from the edge of the protective film layer 20.

Compared to the embodiments described above, the polarizing layer 50 differs in the position and area, and thus, the description below will focus on these differences.

The polarizing layer 50 may be arranged on the protective film layer 20. For example, the polarizing layer 50 may be arranged on a surface opposite to the display panel 10 with respect to the protective film layer 20. In other words, relative positional relations among the display panel 10, the protective film layer 20, and the polarizing layer 50 may be in the order of the display panel 10, the protective film layer 20, and the polarizing layer 50 based on FIG. 7.

The polarizing layer 50 may be positioned so as to be spaced inward from the edge of the protective film layer 20 when viewed in a direction perpendicular to the display panel 10 (Z-axis direction in FIG. 1 and FIG. 2). To put this in another perspective, when viewed in a direction perpendicular to the display panel 10 (in the z-direction in FIGS. 1 and 2), the protective film layer 20 may include a portion that does not overlap the polarizing layer 50. In this case, the area of the polarizing layer 50 may be smaller than the area of the protective film layer 20.

In an embodiment, the polarizing layer 50 may be arranged so that an edge of the polarizing layer 50 is spaced apart inward from the perimeter of the protective film layer 20. To put this in another perspective, it may be said that the protective film layer 20 is arranged to surround the polarizing layer 50 as viewed in a direction perpendicular to the display panel 10 (in the z-direction in FIGS. 1 and 2).

In an embodiment, an area where the polarizing layer 50 and the protective film layer 20 do not overlap each other may correspond to the peripheral area PA of the display device 1. In this case, it may be considered that the polarizing layer 50 is arranged in a position corresponding to the display area DA of the display device 1.

In an optional embodiment, the distance between the edge of the polarizing layer 50 and the edge of the protective film layer 20 may be 300 μm to 500 μm.

In an embodiment, the protective film layer 20 may be arranged to correspond to the display panel 10. For example, as viewed in a direction perpendicular to the display panel 10 (in the z-direction in FIGS. 1 and 2), the edge of the protective film layer 20 may not be spaced apart from the edge of the display panel 10. In this case, the polarizing layer 50 may be spaced apart inward from the edge of the display panel 10 as viewed in a direction perpendicular to the display panel 10 (in the z-direction in FIGS. 1 and 2). Additionally, the area of the polarizing layer 50 may be smaller than the area of the display panel 10.

As described above, as viewed in a direction perpendicular to the display panel 10 (in the z-direction in FIGS. 1 and 2), the polarizing layer 50 may be arranged to be spaced apart inward from the edge of the protective film layer 20 so that tolerance occurring in a lamination process of the polarizing layer 50 and the protective film layer 20 may be compensated for.

Although not shown in FIG. 7, unless different from those described above, the polarizing layer 50 may include the hard coating layer HC described with reference to FIG. 6.

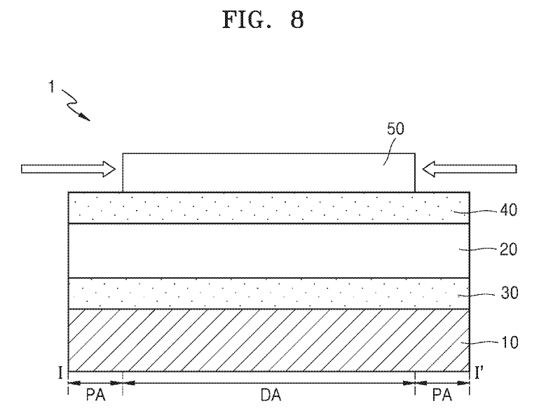

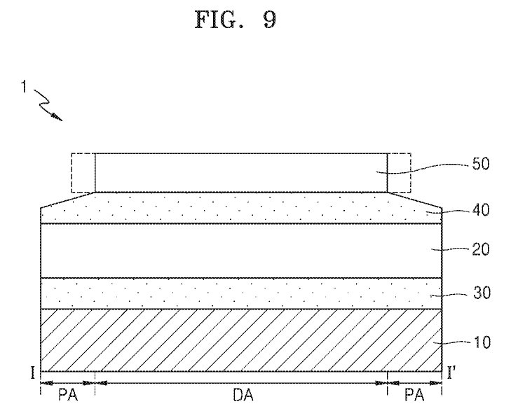

FIGS. 8 and 9 are diagrams illustrating an example of a force acting on a polarizing layer. Specifically, FIG. 8 is a diagram showing the appearance of the display device 1 before the polarizing layer 50 is deformed, and FIG. 9 is a diagram showing the appearance of the display device 1 after the polarizing layer 50 is deformed.

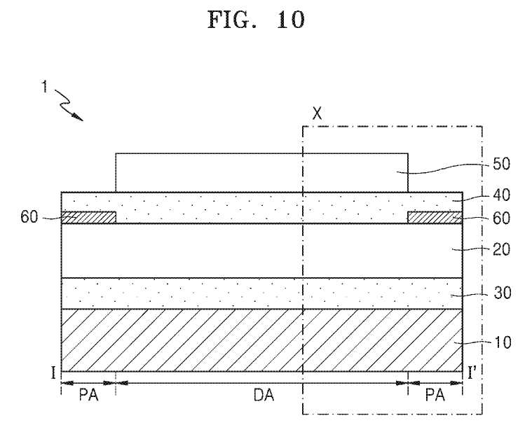

Here, the polarizing layer 50 may correspond to the polarizing layer 50 in the embodiment described with reference to FIG. 6, the polarizing layer 50 in the embodiment described with reference to FIG. 7, or the polarizing layer 50 in the embodiments described below with reference to FIGS. 10 to 13.

Referring to FIGS. 8 and 9, the shape of the polarizing layer 50 may change over time after being arranged on the protective film layer 20. For example, as shown in FIG. 8, the polarizing layer 50 may shrink by receiving a force in a direction, in which side-to-side shrinkage occurs based on FIG. 8, over time after being arranged on the protective film layer 20.

When the polarizing layer 50 shrinks, the protective film layer 20 bonded to the polarizing layer 50 and the display panel 10 bonded to the protective film layer 20 may receive a force in a direction in which unidirectional bending occurs. In other words, according to the present disclosure, the display device 1 may receive a force in a direction in which unidirectional bending occurs due to the shrinkage of the polarizing layer 50. For example, the display device 1 may receive a force, which bends upward, on opposite sides thereof based on FIGS. 8 and 9. This may increase the risk of damage to the display device 1 and reduce the stability of the display device 1.

According to an embodiment of the present disclosure, the first adhesive layer 30 and the second adhesive layer 40 may have different properties. For example, the first adhesive layer 30 and the second adhesive layer 40 may have different storage moduli.

In a specific embodiment, the storage modulus of the first adhesive layer 30 may be greater than the storage modulus of the second adhesive layer 40. In other words, the storage modulus of the second adhesive layer 40 in contact with the polarizing layer 50 may be less than the storage modulus of the first adhesive layer 30.

In an optional embodiment, the storage modulus of the second adhesive layer 40 may be less than 1/6 of the storage modulus of the first adhesive layer 30. As an example, when the storage modulus of the first adhesive layer 30 is 0.3 MPa, the storage modulus of the second adhesive layer 40 may be less than 0.05 MPa.

In an embodiment, the first adhesive layer 30 and the second adhesive layer 40 may have different thicknesses. In a specific embodiment, the thickness of the first adhesive layer 30 may be less than the thickness of the second adhesive layer 40.

In an optional embodiment, the thickness of the second adhesive layer 40 may be 1 to 2 times the thickness of the first adhesive layer 30. For example, when the thickness of the first adhesive layer 30 is 50 µm, the thickness of the second adhesive layer 40 may be 50 µm to 100 µm.

Therefore, when an external force (e.g., shrinkage stress of the polarizing layer 50) is applied, the second adhesive layer 40 may be relatively easily deformed. In other words, according to the present embodiment, when the polarizing layer 50 is deformed, the second adhesive layer 40 may also be deformed along with the deformation of the polarizing layer 50.

For example, as shown in FIGS. 8 and 9, when the polarizing layer 50 shrinks, a surface of the second adhesive layer 40 that is in contact with the polarizing layer 50 among the opposite surfaces of the second adhesive layer 40 may shrink in a direction in which the polarizing layer 50 shrinks. To put this in another perspective, when the polarizing layer 50 shrinks, the second adhesive layer 40 may be expressed as shrinking and being deformed so that one surface of the second adhesive layer 40, which is in contact with the polarizing layer 50 among opposite surfaces of the second adhesive layer 40, has a smaller area than the other surface of the second adhesive layer 40 in order to compensate for the shrinkage of the polarizing layer 50.

In other words, the second adhesive layer 40 may be deformed along with the deformation of the polarizing layer 50, thereby reducing or preventing stress caused by shrinkage of the polarizing layer 50 from being transmitted to the protective film layer 20 and the display panel 10. Additionally, the adhesive layers may be suitable for application to devices having a flexible or bendable characteristic.

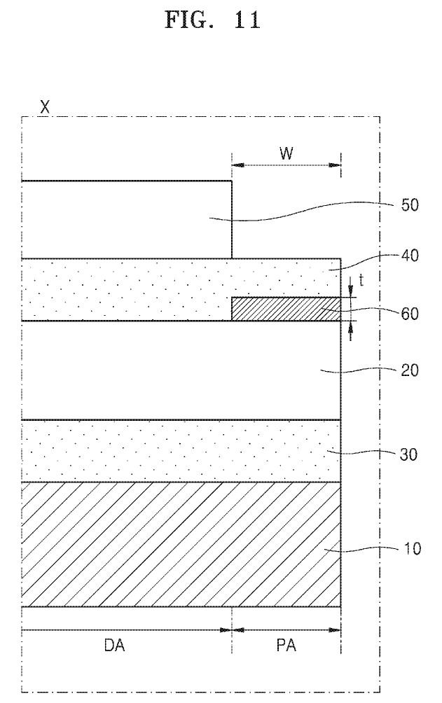

FIG. 10 is a schematic cross-sectional view taken along line I-I' in FIG. 1, according to an embodiment. FIG. 11 is an enlarged view of a region X in FIG. 10.

Referring to FIGS. 10 and 11, a light-shielding member 60 may be further arranged between the protective film layer 20 and the polarizing layer 50.

Compared to the embodiments described above, the display device 1 of the present embodiment may further include the light-shielding member 60. The following description will focus on this difference.

The light-shielding member 60 may be between the protective film layer 20 and the polarizing layer 50.

The light-shielding member 60 may block light from penetrating into unintended locations. For example, the light-shielding member 60 may reduce or prevent a phenomenon, i.e., light leakage, in which light passing through the protective film layer 20 passes through the peripheral area PA of the display device 1. Here, the light-shielding member 60 may be referred to as a black matrix (BM) or a light-leakage prevention member but is not limited to these terms or expressions.

The light-shielding member 60 may include a material that does not transmit light. For example, the light-shielding member 60 may include carbon black.

The light-shielding member 60 may be in contact with the protective film layer 20. To put this in another perspective, it may be said that the light-shielding member 60 may be attached to one surface of the protective film layer 20. For example, the light-shielding member 60 may be attached to the top surface of the protective film layer 20, based on FIGS. 10 and 11.

An adhesive layer may be arranged to surround at least a portion of the light-shielding member 60. To put this in another perspective, it may be said that the light-shielding member 60 is arranged inside the adhesive layer.

For example, the second adhesive layer 40 may be arranged to surround at least a portion of the light-shielding member 60. In other words, the light-shielding member 60 may be arranged inside the second adhesive layer 40. The second adhesive layer 40 may be thicker than the light-shielding member 60.

In a specific embodiment, the light-shielding member 60 may have a thickness less than half the thickness of the second adhesive layer 40. Here, the thickness of the second adhesive layer 40 may refer to the thickness thereof in a direction parallel with the direction of a thickness "t" of the light-shielding member 60, based on FIG. 11.

In a specific embodiment, the light-shielding member 60 may have a thickness less than 3/10 of the thickness of the second adhesive layer 40. Here, the thickness of the second adhesive layer 40 may refer to a thickness thereof in a direction parallel with the direction of the thickness "t" of the light-shielding member 60, based on FIG. 11.

When the light-shielding member 60 has a thickness less than half the thickness of the second adhesive layer 40, even if the second adhesive layer 40 shrinks due to viscoelasticity, the second adhesive layer 40 may completely cover the light-shielding member 60. In other words, when the light-shielding member 60 is formed to have a thickness greater than half the thickness of the second adhesive layer 40, there may be a problem in that the light-shielding member 60 is exposed to the outside due to shrinkage of the second adhesive layer 40.

When the light-shielding member 60 has a thickness less than 3/10 of the thickness of the second adhesive layer 40, the light-shielding member 60 may be completely covered by the second adhesive layer 40 despite the process variation of shrinkage of the second adhesive layer 40.

In an optional embodiment, the thickness "t" of the light-shielding member 60 may be 15 μm. As shown in FIG. 11, the light-shielding member 60 may have a surface in contact with the protective film layer 20, another surface exposed to the outside, and the other two surfaced surrounded by the second adhesive layer 40. Accordingly, the adhesion between the polarizing layer 50 and the second adhesive layer 40 may be improved, and the light-leakage prevention efficiency of the light-shielding member 60 may be improved.

In an embodiment, the light-shielding member 60 may overlap the peripheral area PA. For example, a width W of the light-shielding member 60 may be the same as a width of the peripheral area PA. In addition, when the light-shielding member 60 is applied to the embodiment described with reference to FIG. 7, the width W of the light-shielding member 60 may be greater than or equal to the distance between the edge of the polarizing layer 50 and the edge of the protective film layer 20. In an optional embodiment, the width W of the light-shielding member 60 may be 300 μm to 500 μm. When the width W of the light-shielding member 60 is less than 300 μm, light leakage may occur. When the width W of the light-shielding member 60 is greater than 500 μm, the display function of the display device 1 may deteriorate.

In an embodiment, the light-shielding member 60 may be arranged along the edge of the protective film layer 20. For example, the light-shielding member 60 may be arranged on a surface of the protective film layer 20 along the perimeter of the protective film layer 20. Accordingly, the light-shielding member 60 may prevent or reduce light leakage in the entire perimeter of the protective film layer 20.

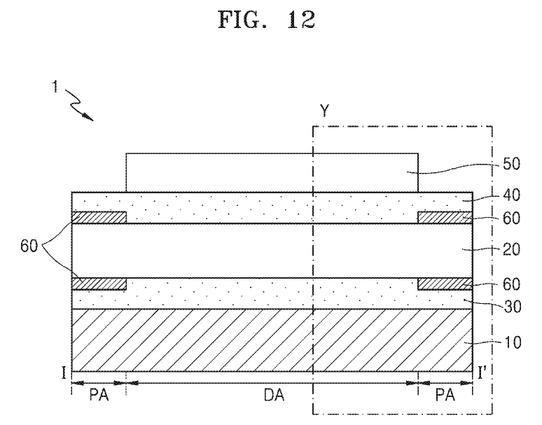

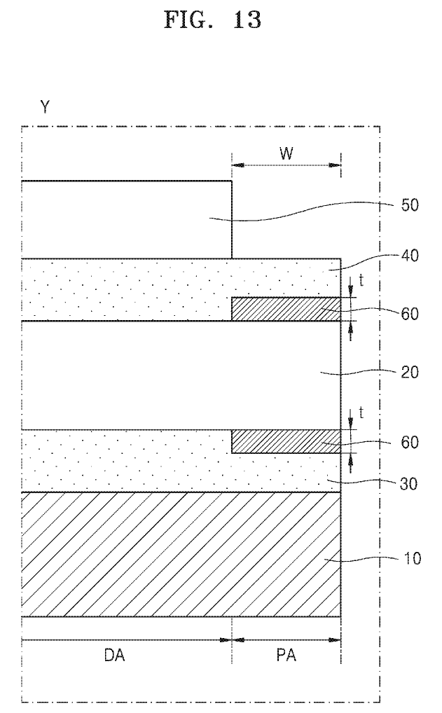

FIG. 12 is a schematic cross-sectional view taken along line I-I' in FIG. 1, according to an embodiment. FIG. 13 is an enlarged view of a region Y in FIG. 12.

Referring to FIGS. 12 and 13, the light-shielding member 60 may be further arranged between the protective film layer 20 and the display panel 10.

Compared to the embodiments described above, the display device 1 of the present embodiment differs in that the light-shielding member 60 may be arranged on each of opposite surfaces of the protective film layer 20. The following description will focus on this difference.

The light-shielding member 60 may be placed between the protective film layer 20 and the polarizing layer 50 and between the protective film layer 20 and the display panel 10.

The light-shielding member 60 may block light from penetrating into unintended locations. For example, the light-shielding member 60 may reduce or prevent a phenomenon, i.e., light leakage, in which light passing through the protective film layer 20 passes through the peripheral area PA of the display device 1.

The light-shielding member 60 may include a material that does not transmit light. For example, the light-shielding member 60 may include carbon black.

The light-shielding member 60 may be in contact with the protective film layer 20. To put this in another perspective, it may be said that the light-shielding member 60 may be attached to each of opposite surfaces of the protective film layer 20. For example, the light-shielding member 60 may be attached to each of the top and bottom surfaces of the protective film layer 20, based on FIGS. 12 and 13.

An adhesive layer may be arranged to surround at least a portion of the light-shielding member 60. To put this in another perspective, it may be said that the light-shielding member 60 may be arranged inside the adhesive layer.

For example, the first adhesive layer 30 may be arranged to surround at least a portion of the light-shielding member 60 attached to the bottom surface of the protective film layer 20, based on FIGS. 12 and 13. In other words, the light-shielding member 60 may be arranged inside the first adhesive layer 30. Additionally, the second adhesive layer 40 may be arranged to surround at least a portion of the light-shielding member 60 attached to the top surface of the protective film layer 20, based on FIGS. 12 and 13. In other words, the light-shielding member 60 may be arranged on inside the second adhesive layer 40. Accordingly, the adhesion between the polarizing layer 50 and the second adhesive layer 40 may be improved, and the light leakage prevention efficiency of the light-shielding member 60 may be improved.

In an embodiment, the light-shielding member 60 may have the thickness "t" that is less than half the thickness of the first adhesive layer 30 or the second adhesive layer 40.

In a specific embodiment, the light-shielding member 60 may have the thickness "t" that is less than half the thickness of the first adhesive layer 30. Here, the thickness of the first adhesive layer 30 may refer to a thickness in a direction parallel with the direction of the thickness "t" of the light-shielding member 60, based on FIG. 13.

As a specific example, the light-shielding member 60 may have the thickness "t" that is less than 3/10 of the thickness of the first adhesive layer 30. Here, the thickness of the first adhesive layer 30 may refer to a thickness in a direction parallel with the direction of the thickness "t" of the light-shielding member 60, based on FIG. 13.

When the light-shielding member 60 has the thickness "t" that is less than half the thickness of the first adhesive layer 30, even if the first adhesive layer 30 shrinks due to viscoelasticity, the first adhesive layer 30 may completely cover the light-shielding member 60 In other words, when the light-shielding member 60 has the thickness "t" that is greater than half the thickness of the first adhesive layer 30, there may be a problem in that the light-shielding member 60 is exposed to the outside due to shrinkage of the first adhesive layer 30.

When the light-shielding member 60 has the thickness "t" that is less than 3/10 of the thickness of the first adhesive layer 30, the light-shielding member 60 may be completely covered by the first adhesive layer 30 despite the process variation of shrinkage of the first adhesive layer 30.

In this case, the thickness "t" of the light-shielding member 60 may be less than 1/2 of the thickness of the second adhesive layer 40 or less than 3/10 of the thickness of the second adhesive layer 40, as described above with reference to FIGS. 10 and 11, and thus, detailed descriptions thereof will be omitted.

In an embodiment, the light-shielding member 60 may overlap the peripheral area PA. For example, the width W of the light-shielding member 60 may be the same as the width of the peripheral area PA. In addition, when the light-shielding member 60 is applied to the embodiment described with reference to FIG. 7, the width W of the light-shielding member 60 may be greater than or equal to the distance between the edge of the polarizing layer 50 and the edge of the protective film layer 20. In an optional embodiment, the width W of the light-shielding member 60 may be 300 μm to 500 μm. When the width W of the light-shielding member 60 is less than 300 μm, light leakage may occur. When the width W of the light-shielding member 60 is greater than 500 μm, the display function of the display device 1 may deteriorate.

In an embodiment, the light-shielding member 60 may be arranged along the edge of the protective film layer 20. For example, the light-shielding member 60 may be arranged along the perimeter of each of opposite surfaces of the protective film layer 20. Accordingly, the light-shielding member 60 may prevent or reduce light leakage in the entire perimeter of the protective film layer 20.

As described above, since the light-shielding member 60 is arranged on each of the opposite surfaces of the protective film layer 20, light leakage may be more completely prevented or efficiently reduced by the light-shielding member 60.

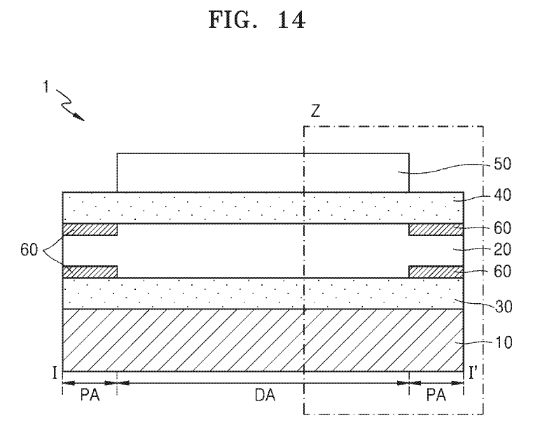

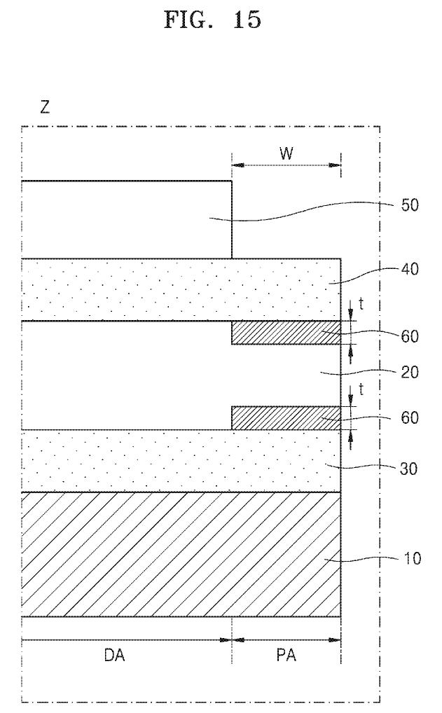

FIG. 14 is a schematic cross-sectional view taken along line I-I' in FIG. 1, according to an embodiment. FIG. 15 is an enlarged view of a region Z in FIG. 14.

Referring to FIGS. 14 and 15, the light-shielding member 60 may be arranged such that at least a portion of the light-shielding member 60 is introduced into the protective film layer 20.

Compared to the embodiments described above, the display device 1 of the present embodiment differs in that the light-shielding member 60 may be arranged such that at least a portion of the light-shielding member 60 is introduced into the protective film layer 20. The following description will focus on this difference.

The light-shielding member 60 may be arranged in at least one of the locations between the protective film layer 20 and the polarizing layer 50 and between the protective film layer 20 and the display panel 10.

In an embodiment, the light-shielding member 60 may be arranged in each of both locations between the protective film layer 20 and the polarizing layer 50 and between the protective film layer 20 and the display panel 10.

The light-shielding member 60 may block light from penetrating into unintended locations. For example, the light-shielding member 60 may reduce or prevent a phenomenon, i.e., light leakage, in which light passing through the protective film layer 20 passes through the peripheral area PA of the display device 1.

The light-shielding member 60 may include a material that does not transmit light. For example, the light-shielding member 60 may include carbon black.

The light-shielding member 60 may be arranged such that at least a portion of the light-shielding member 60 is introduced into the protective film layer 20. To put this in another perspective, it may be said that the light-shielding member 60 is arranged on each of a surface of the first adhesive layer 30 and a surface of the second adhesive layer 40 and arranged inside the protective film layer 20. For example, the light-shielding member 60 may be arranged such that at least a portion of the light-shielding member 60 is introduced into the inside of the protective film layer 20 from the top surface of the first adhesive layer 30, based on FIGS. 14 and 15. Additionally, the light-shielding member 60 may be arranged such that at least a portion of the light-shielding member 60 is introduced into the inside of the protective film layer 20 from the bottom surface of the second adhesive layer 40.

In this case, the protective film layer 20 may be arranged to surround at least a portion of the light-shielding member 60. To put this in another perspective, it may be said that the light-shielding member 60 may be arranged inside the protective film layer 20. For example, the protective film layer 20 may be arranged to surround at least a portion of the light-shielding member 60 arranged on the top surface of the first adhesive layer 30 and at least a portion of the light-shielding member 60 arranged on the bottom surface of the second adhesive layer 40, based on FIGS. 14 and 15.

Accordingly, the adhesion between the protective film layer 20 and the display panel 10 and the adhesion between the protective film layer 20 and the polarizing layer 50 may be improved, and the light leakage prevention efficiency of the light-shielding member 60 may be improved.

In an embodiment, the light-shielding member 60 may overlap the peripheral area PA. For example, the width W of the light-shielding member 60 may be the same as the width of the peripheral area PA. In addition, when the light-shielding member 60 is applied to the embodiment described with reference to FIG. 7, the width W of the light-shielding member 60 may be greater than or equal to the distance between the edge of the polarizing layer 50 and the edge of the protective film layer 20. In an optional embodiment, the width W of the light-shielding member 60 may be 300 μm to 500 μm. When the width W of the light-shielding member 60 is less than 300 μm, light leakage may occur. When the width W of the light-shielding member 60 is greater than 500 μm, the display function of the display device 1 may deteriorate.

In an embodiment, the light-shielding member 60 may be arranged along the edge of the protective film layer 20. For example, the light-shielding member 60 may be arranged along the perimeter of each of opposite surfaces of the protective film layer 20. Accordingly, the light-shielding member 60 may prevent or reduce light leakage in the entire perimeter of the protective film layer 20.

As described above, since the light-shielding member 60 is arranged on each of the opposite surfaces of the protective film layer 20 such that at least a portion of the light-shielding member 60 is introduced into the protective film layer 20, light leakage may be more completely prevented or efficiently reduced by the light-shielding member 60.

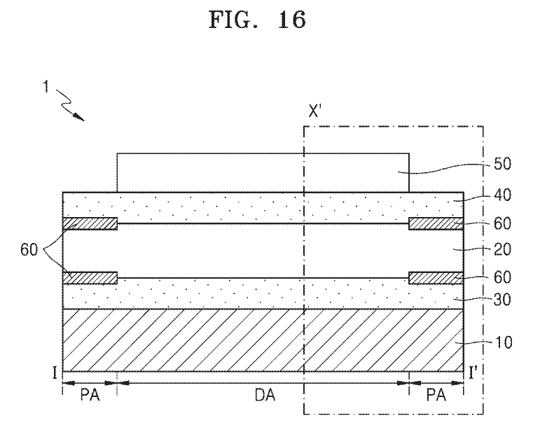

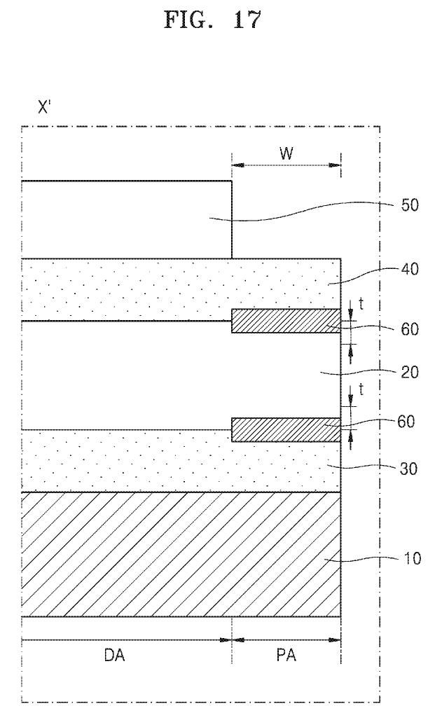

FIG. 16 is a schematic cross-sectional view taken along line I-I' in FIG. 1, according to an embodiment. FIG. 17 is an enlarged view of a region X' in FIG. 16.

Compared to the embodiments described above, the display device 1 of the present embodiment differs in that the light-shielding member 60 is arranged such that at least a portion of the light-shielding member 60 is introduced into each of the protective film layer 20 and an adhesive layer. The following description will focus on this difference.

The light-shielding member 60 may be arranged in at least one of the locations between the protective film layer 20 and the polarizing layer 50 and between the protective film layer 20 and the display panel 10.

In an embodiment, the light-shielding member 60 may be arranged in each of both locations between the protective film layer 20 and the polarizing layer 50 and between the protective film layer 20 and the display panel 10.

The light-shielding member 60 may block light from penetrating into unintended locations. For example, the light-shielding member 60 may reduce or prevent a phenomenon, i.e., light leakage, in which light passing through the protective film layer 20 passes through the peripheral area PA of the display device 1.

The light-shielding member 60 may include a material that does not transmit light. For example, the light-shielding member 60 may include carbon black.

The light-shielding member 60 may be arranged such that at least a portion of the light-shielding member 60 is introduced into each of the protective film layer 20 and an adhesive layer.

In a specific embodiment, the light-shielding member 60 may be arranged such that at least a portion of the light-shielding member 60 is introduced into the protective film layer 20 and at least a portion of the light-shielding member 60 is introduced into the first adhesive layer 30. To put this in another perspective, the light-shielding member 60 may be arranged between the protective film layer 20 and the first adhesive layer 30 such that at least a portion of the light-shielding member 60 is introduced into each of the protective film layer 20 and the first adhesive layer 30. In addition, the light-shielding member 60 may be arranged such that at least a portion of the light-shielding member 60 is introduced into each of the protective film layer 20 and the second adhesive layer 40. To put this in another perspective, the light-shielding member 60 may be arranged between the protective film layer 20 and the second adhesive layer 40 such that at least a portion of the light-shielding member 60 is introduced into each of the protective film layer 20 and the second adhesive layer 40.

In this case, the light-shielding member 60 between the protective film layer 20 and the first adhesive layer 30 may be at least partially surrounded by each of the protective film layer 20 and the first adhesive layer 30. For example, based on FIGS. 16 and 17, the light-shielding member 60 in an upper portion of the first adhesive layer 30 may be at least partially surrounded by each of the first adhesive layer 30 and the protective film layer 20.

In addition, the light-shielding member 60 between the protective film layer 20 and the second adhesive layer 40 may be at least partially surrounded by each of the protective film layer 20 and the second adhesive layer 40. For example, based on FIGS. 16 and 17, the light-shielding member 60 in a lower portion of the second adhesive layer 40 may be at least partially surrounded by each of the second adhesive layer 40 and the protective film layer 20.

Accordingly, the adhesion between the protective film layer 20 and the display panel 10 and the adhesion between the protective film layer 20 and the polarizing layer 50 may be improved, and the light leakage prevention efficiency of the light-shielding member 60 may be improved.

As an example, the light-shielding member 60 may be positioned to overlap with the peripheral area PA. For example, the width W of the light-shielding member 60 may be the same as the width of the peripheral area PA. In addition, when the light-shielding member 60 is applied to the embodiment described with reference to FIG. 7, the width W of the light-shielding member 60 may be greater than or equal to the distance between the edge of the polarizing layer 50 and the edge of the protective film layer 20. In an optional embodiment, the width W of the light-shielding member 60 may be 300 μm to 500 μm. When the width W of the light-shielding member 60 is less than 300 μm, light leakage may occur. When the width W of the light-shielding member 60 is greater than 500 μm, the display function of the display device 1 may deteriorate.

In an embodiment, the light-shielding member 60 may be arranged along the edge of the protective film layer 20. For example, the light-shielding member 60 may be arranged along the perimeter of each of opposite surfaces of the protective film layer 20. Accordingly, the light-shielding member 60 may prevent or reduce light leakage in the entire perimeter of the protective film layer 20.

As described above, since the light-shielding member 60 is arranged in each of the opposite surfaces of the protective film layer 20 such that at least a portion of the light-shielding member 60 is introduced into each of the protective film layer 20 and an adhesive layer, light leakage may be more completely prevented or efficiently reduced by the light-shielding member 60.

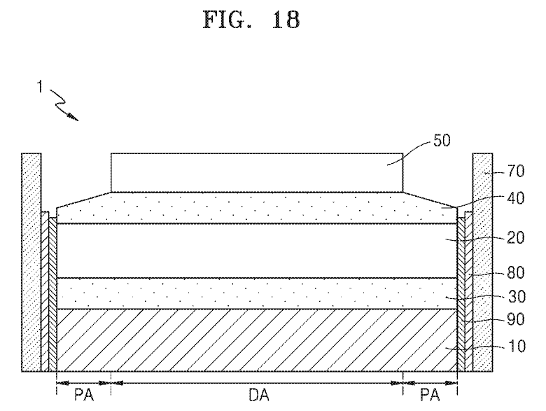

FIG. 18 is a schematic cross-sectional view taken along line I-I' in FIG. 1, according to an embodiment.

Compared to the embodiments described above, the display device 1 of the present embodiment differs in that a housing 70 may be arranged along at least a portion of the outer perimeter of the display panel 10. The following description will focus on this difference.

Referring to FIG. 18, the housing 70 may be placed on at least a portion of the outer periphery of the display panel 10.

In an embodiment, the housing 70 may be arranged along the perimeter of the display panel 10 to cover the perimeter of the display panel 10. For example, the housing 70 may be arranged along the side surface of the display panel 10. In addition, the housing 70 may not cover an upper portion of the display panel 10. To put this in another perspective, the housing 70 may cover the perimeter of the display panel 10 but not the upper portion of the display panel 10.

In an embodiment, the housing 70 may be high enough to cover the side surface of at least one selected from the group consisting of the display panel 10, the protective film layer 20, the first adhesive layer 30, the second adhesive layer 40, and the polarizing layer 50, which are arranged on the display panel 10. In a specific embodiment, the housing 70 may be high enough to cover the side surface of the display panel 10 and the side surfaces of all the protective film layer 20, the first adhesive layer 30, the second adhesive layer 40, and the polarizing layer 50, which are arranged on the display panel 10.

Therefore, the expression “the side surface of the display panel 10” may not only refer to the side surface of the display panel 10 but also be interpreted as including the side surfaces of multiple layers on the display panel 10.

Although the light-shielding member 60 is not shown in FIG. 18, the light-shielding member 60 may be further arranged between several layers on the display panel 10, as in the embodiments described above with reference to FIGS. 6 to 17.

In an embodiment, an attachment portion 80 may be further arranged on a surface of the housing 70. For example, the attachment portion 80 may be arranged on a surface of housing 70, which faces the display panel 10 among opposite surfaces of the housing 70.

The attachment portion 80 may be arranged on one surface of the housing 70 and may allow the housing 70 to be attached to the side surface of the display panel 10.

In an embodiment, a sealing portion 90 may be further arranged on the side surface of the display panel 10. The sealing portion 90 may allow the side surface of the housing 70 to be more stably attached to the side surface of the display panel 10.

In other words, the attachment portion 80 and the sealing portion 90 may be arranged between the display panel 10 and the housing 70 to strongly attach the housing 70 to the side surface of the display panel 10.

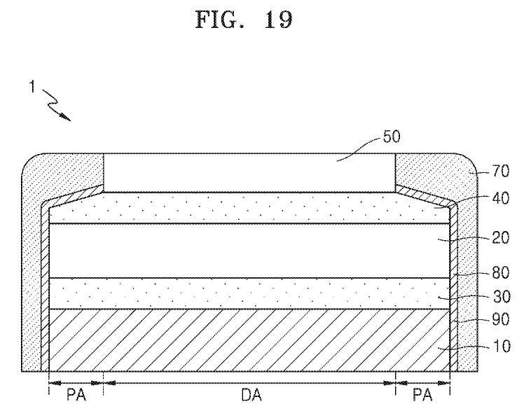

FIG. 19 is a schematic cross-sectional view taken along line I-I' in FIG. 1, according to an embodiment.

Compared to the embodiments described above, the display device 1 of the present embodiment differs in that the housing 70 may be arranged along at least a portion of the outer side of the display panel 10. The following description will focus on this difference.

Referring to FIG. 19, the housing 70 may be arranged along at least a portion of the outer side of the display panel 10.

The housing 70 may be of a bezel type. For example, the display panel 10 may be inserted into the housing 70 such that the housing 70 surrounds the outer side of the display panel 10.

The housing 70 may cover the perimeter of the display panel 10 and the perimeter of the protective film layer 20, the first adhesive layer 30, the second adhesive layer 40, and the polarizing layer 50, which are disposed on the display panel 10.

In an embodiment, the housing 70 may be arranged to surround the side surfaces of the display panel 10, the protective film layer 20, the first adhesive layer 30, the second adhesive layer 40, and the polarizing layer 50. At this time, the housing 70 may overlap at least a portion of the side surface of the polarizing layer 50. For example, the housing 70 may be in contact with the side surface of the polarizing layer 50. In addition, the housing 70 may overlap at least a portion of the side surface of the second adhesive layer 40.

Although the light-shielding member 60 is not shown in FIG. 19, the light-shielding member 60 may be further arranged between several layers on the display panel 10, as in the embodiments described above with reference to FIGS. 6 to 17.

In an embodiment, an attachment portion 80 may be further arranged on a surface of the housing 70. For example, the attachment portion 80 may be arranged on a surface of housing 70, which faces the display panel 10 among opposite surfaces of the housing 70.

The attachment portion 80 may be arranged on one surface of the housing 70 and may allow the housing 70 to be attached to the side surface of the display panel 10.

At this time, when an upper portion of the second adhesive layer 40 is inclined due to shrinkage of the polarizing layer 50, the attachment portion 80 may be arranged along the incline of the second adhesive layer 40.

Although it is illustrated in FIG. 19 that the attachment portion 80 is continuously arranged on a surface of the housing 70, a plurality of attachment portions 80 may be arranged spaced apart from each other on a surface of the housing 70.

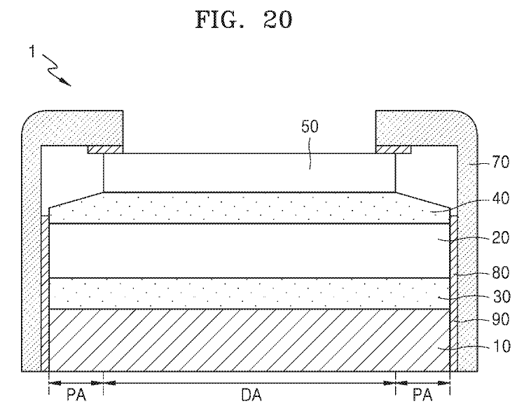

FIG. 20 is a schematic cross-sectional view taken along line I-I' in FIG. 1, according to an embodiment.

Compared to the embodiments described above, the display device 1 of the present embodiment differs in that the housing 70 may be arranged along at least a portion of the outer side of the display panel 10. The following description will focus on this difference.

Referring to FIG. 20, the housing 70 may be arranged along at least a portion of the outer side of the display panel 10.

The housing 70 may be of a bezel type. For example, the display panel 10 may be inserted into the housing 70 such that the housing 70 surrounds the outer side of the display panel 10.

The housing 70 may cover the perimeter of the display panel 10 and the perimeter of the protective film layer 20, the first adhesive layer 30, the second adhesive layer 40, and the polarizing layer 50, which are disposed on the display panel 10.

In an embodiment, the housing 70 may be arranged to surround the side surfaces of the display panel 10, the protective film layer 20, the first adhesive layer 30, and the second adhesive layer 40. At this time, the housing 70 may be positioned to overlap the upper portion of the polarizing layer 50. Additionally, the housing 70 may overlap at least a portion of the top surface of the second adhesive layer 40. For example, the housing 70 may extend further from a height that covers the entire side surface of each of the display panel 10, the protective film layer 20, the first adhesive layer 30, and the second adhesive layer 40 and may bend in a direction toward the polarizing layer 50 so as to overlap at least a portion of the surface of the polarizing layer 50. To put this in another perspective, an upper portion of the housing 70 may surround at least a portion of the perimeter of the top surface of the polarizing layer 50 so that a portion of the polarizing layer 50 may be exposed.

Although the light-shielding member 60 is not shown in FIG. 20, the light-shielding member 60 may be further arranged between several layers on the display panel 10, as in the embodiments described above with reference to FIGS. 6 to 17.

In an embodiment, an attachment portion 80 may be further arranged on a surface of the housing 70. For example, the attachment portion 80 may be arranged on a surface of housing 70, which faces the display panel 10 among opposite surfaces of the housing 70.

The attachment portion 80 may be arranged on one surface of the housing 70 and may allow the housing 70 to be attached to the side surface of the display panel 10.

In an embodiment, the attachment portion 80 may be arranged between the display panel 10 and the housing 70. In some embodiments, the attachment portion 80 may also be arranged between the housing 70 and each of the protective film layer 20, the first adhesive layer 30, and the second adhesive layer 40, which are on the display panel 10. In addition, the attachment portion 80 may also be arranged between the housing 70 and the top surface of the polarizing layer 50. In other words, since the housing 70 overlaps the top surface of the polarizing layer 50, the attachment portion 80 may be arranged between the top surface of the housing 70 and the polarizing layer 50 so that the housing 70 may be stably attached to the top surface of the polarizing layer 50.

A method of manufacturing the display device 1, according to an embodiment of the present disclosure, will be described below For convenience of description, the same content as that describing the display device 1 or the content that may be easily applied by one of ordinary skill in the art will be omitted or briefly described.

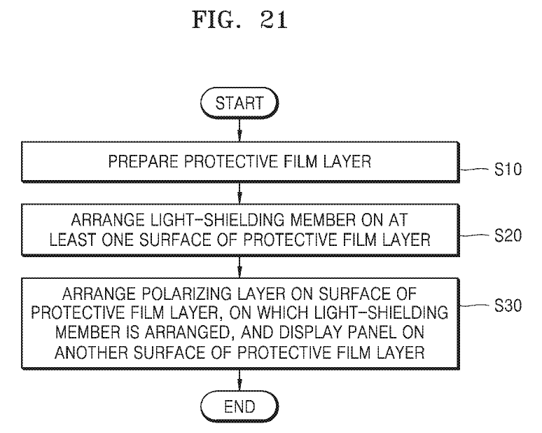

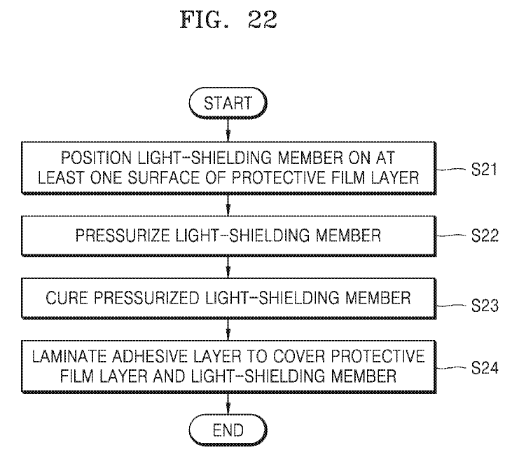

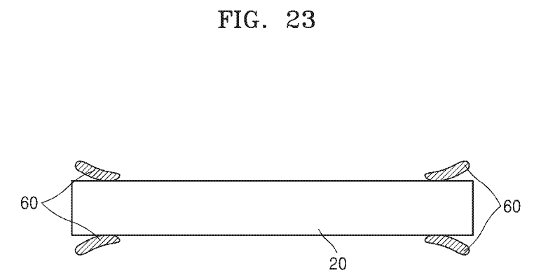

FIGS. 21 and 22 are schematic flowcharts of a method of manufacturing the display device 1, according to an embodiment of the present disclosure. FIGS. 23 to 26 are diagrams schematically illustrating a method of manufacturing the display device 1, according to an embodiment of the present disclosure.

Referring to FIGS. 21 to 26, according to an embodiment of the present disclosure, a method of manufacturing the display device 1 may include preparing a protective film layer 20 in operation S10, arranging a light-shielding member 60 on at least one surface of the protective film layer 20 in operation S20, and arranging a polarizing layer 50 on a surface of the protective film layer 20, on which the light-shielding member 60 is arranged, and a display panel 10 on an opposite surface of the protective film layer 20 in operation S30.

Here, the protective film layer 20, the light-shielding member 60, and the display panel 10 may correspond to those in the embodiments described above.

In an embodiment, operation S20 of arranging the light-shielding member 60 on at least one surface of the protective film layer 20 may include arranging the light-shielding member 60 on at least one surface of the protective film layer 20 in operation S21, pressurizing the light-shielding member 60 in operation S22, curing the light-shielding member 60 in operation S23, and laminating an adhesive layer to the protective film layer 20 to cover the protective film layer 20 and the light-shielding member 60 in operation S24.

Referring to FIG. 23, in operation S21 of arranging the light-shielding member 60 on at least one surface of the protective film layer 20, at least a portion of the light-shielding member 60 may be brought into contact with at least one surface of the protective film layer 20. For example, the light-shielding member 60 may be prepared in a ductile state without being cured. The light-shielding member 60 may be arranged such that at least a portion of the light-shielding member 60 is in contact with the protective film layer 20.

In an embodiment, the light-shielding member 60 may be positioned on only one surface, i.e., either the top or bottom surface, of the protective film layer 20, based on FIG. 23.

In an embodiment, the light-shielding member 60 may be positioned on each of opposite surfaces, i.e., the top and bottom surfaces, of the protective film layer 20, based on FIG. 23.

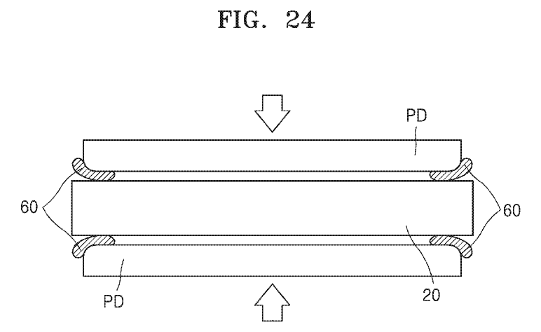

Referring to FIG. 24, in operation S22 of pressurizing the light-shielding member 60, the light-shielding member 60 may be pressurized to come into contact with the protective film layer 20 over a large area. For example, the light-shielding member 60 prepared in a ductile state may be brought into contact with the protective film layer 20 over a wide area by pressurization.

In an embodiment, the pressurizing of the light-shielding member 60 may be performed using a pad PD. The pad PD may refer to a member that contacts at least a portion of the light-shielding member 60 and presses the light-shielding member 60 toward the protective film layer 20.

In an embodiment, when the light-shielding member 60 is arranged on each of opposite surfaces of the protective film layer 20, the pad PD may press the light-shielding member 60 on each of the opposite surfaces of the protective film layer 20 in a direction toward the protective film layer 20. In an optional embodiment, pads PD may simultaneously press light-shielding members 60, which are respectively arranged on the opposite surfaces of the protective film layer 20, toward the protective film layer 20.

In an embodiment, a light-shielding member 60 may be prepared in a shape corresponding to the perimeter of the protective film layer 20. In this case, the light-shielding member 60 may be positioned along the perimeter of the protective film layer 20, and a pad PD may press the light-shielding member 60 to arrange the light-shielding member 60 along the perimeter of the protective film layer 20.

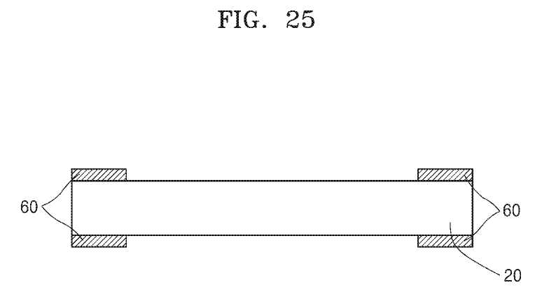

Referring to FIG. 25, operation S23 of curing the light-shielding member 60 that has been pressurized may be performed through thermal curing. In other words, the light-shielding member 60 positioned on at least one surface of the protective film layer 20 and pressurized may be cured by a curing process.

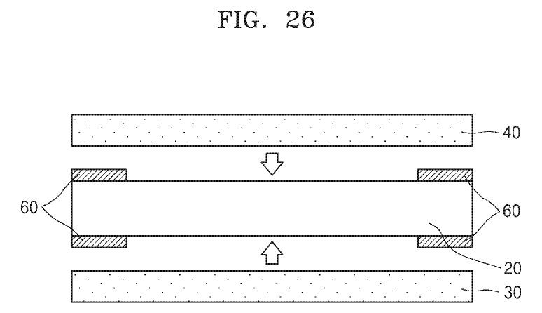

Referring to FIG. 26, in operation S24 of laminating the adhesive layer to the protective film layer 20, the adhesive layer may be laminated to each of opposite surfaces of the protective film layer 20. For example, an operation of laminating an adhesive layer may include laminating the adhesive layer on each of opposite surfaces of the protective film layer 20. The laminating of the adhesive layer may be performed to cover the protective film layer 20 and the light-shielding member 60.

In an embodiment, in operation S24 of laminating the adhesive layer to the protective film layer 20, the adhesive layer may be laminated to a thickness greater than that of the light-shielding member 60. Accordingly, the adhesive layer may be formed to surround at least a portion of the light-shielding member 60.

In an embodiment, operation S24 of laminating the adhesive layer to the protective film layer 20 may include laminating a first adhesive layer 30 to a surface of the protective film layer 20 and laminating a second adhesive layer 40, which has a different storage modulus than the first adhesive layer 30, to an opposite surface of the protective film layer 20. Here, the first adhesive layer 30 may be an adhesive layer that is to be arranged between the protective film layer 20 and the display panel 10, and the second adhesive layer 40 may be an adhesive layer that is to be arranged between the protective film layer 20 and the polarizing layer 50.

In an optional embodiment, the storage modulus of the first adhesive layer 30 may be greater than the storage modulus of the second adhesive layer 40. Accordingly, the display device 1 manufactured using the method of the present embodiment may compensate for a force applied thereto in a direction in which the display device 1 is unidirectionally bent.

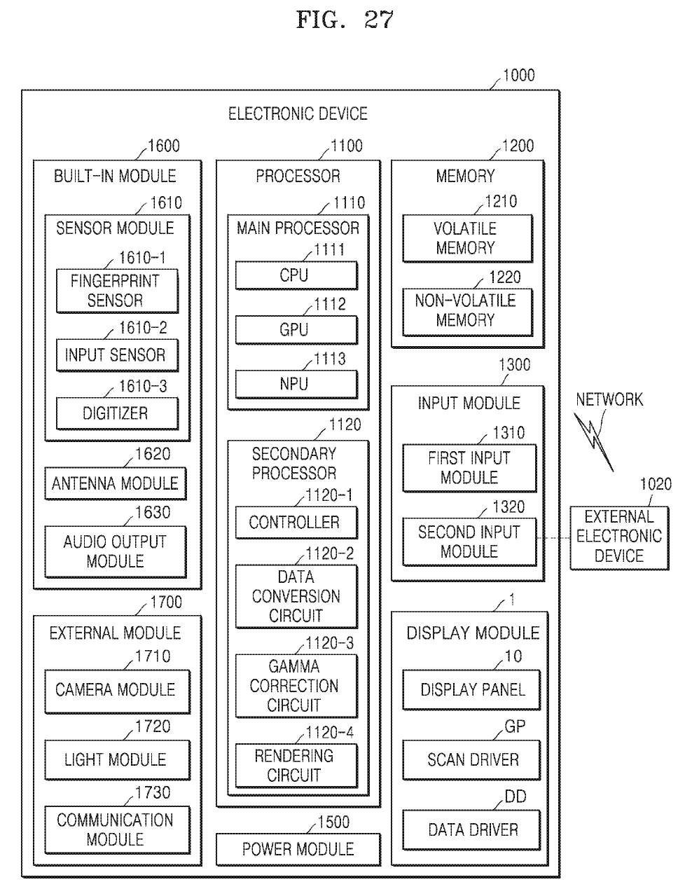

FIG. 27 is a block diagram schematically illustrating an example of an electronic device 1000 according to embodiments of the present disclosure.

Referring to FIG. 27, the electronic device 1000 may output various kinds of information through the display device 1 on an operating system. At this time, the display device 1 may be the one that are illustrated in FIGS. 1 to 26 and described with reference to FIGS. 1 to 26. When a processor 1100 executes an application stored in a memory 1200, the display device 1 may provide application information to a user through the display panel 10.

The processor 1100 may obtain external input through an input module 1300 or a sensor module 1610 and execute an application corresponding to the external input. For example, when a user selects a camera icon displayed on the display panel 10, the processor 1100 may obtain user input through an input sensor 1610-2 and activate a camera module 1710. The processor 1100 may transmit image data, which corresponds to a captured image acquired through the camera module 1710, to the display device 1. The display device 1 may display an image corresponding to the captured image through the display panel 10.

For example, when personal information authentication is performed on the display device 1, a fingerprint sensor 1610-1 may acquire input fingerprint information as input data. The processor 1100 may compare the input data acquired through the fingerprint sensor 1610-1 with authentication data stored in the memory 1200 and may execute an application according to a result of the comparison. The display device 1 may display information, which is executed according to the logic of the application, through the display panel 10.

For example, when a music streaming icon displayed on the display device 1 is selected, the processor 1100 may obtain user input through the input sensor 1610-2 and activate a music streaming application stored in the memory 1200. When a music execution command is input on the music streaming application, the processor 1100 may activate an audio output module 1630 to provide a user with audio information corresponding to the music execution command.

The operation of the electronic device 1000 has been briefly described above The configuration of the electronic device 1000 is described in detail below. Some of the components of the electronic device 1000 described below may be integrated and provided as a single component, and one component may be provided as two or more separate components.

Referring to FIG. 27, the electronic device 1000 may communicate with an external electronic device 1020 through a network (e.g., a short-range wireless communication network or a long-range wireless communication network). According to an embodiment, the electronic device 1000 may include the processor 1100, the memory 1200, the input module 1300, the display device 1, a power module 1500, a built-in module 1600, and an external module 1700. According to an embodiment, the electronic device 1000 may have at least one of the above-described components omitted or one or more other components added. According to an embodiment, some (e.g., the sensor module 1610, an antenna module 1620, or the audio output module 1630) of the components described above may be integrated into another component (e.g., the display device 1).

The processor 1100 may execute software to control at least one other component (e.g., a hardware or software component) of the electronic device 1000 connected to the processor 1100 and perform various types of data processing or operation. According to an embodiment, for at least part of data processing or operation, the processor 1100 may store a command or data, which is received from another component (e.g., the input module 1300, the sensor module 1610, or a communication module 1730), in volatile memory 1210, may process the command or data stored in the volatile memory 1210, and may store result data in non-volatile memory 1220.

The processor 1100 may include a main processor 1110 and a secondary processor 1120. The main processor 1110 may include one or more of a central processing unit (CPU) 1111 and an application processor (AP). The main processor 1110 may further include one or more of a graphics processing unit (GPU) 1112, a communication processor (CP), and an image signal processor (ISP). The main processor 1110 may further include a neural processing unit (NPU) 1113. The NPU 1113 may be a processor specialized in processing artificial intelligence models. Artificial intelligence models may be created through machine learning. An artificial intelligence model may include multiple artificial neural network layers. An artificial neural network may include, but not limited to, a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination thereof. An artificial intelligence model may additionally or alternatively include a software structure in addition to a hardware structure. At least two of the processing units and processors described above may be implemented as a single integrated configuration (e.g., a single chip), or the processing units and processors may be individually implemented as independent configurations (e.g., multiple chips).

The secondary processor 1120 may include a controller 1120-1. The controller 1120-1 may include an interface conversion circuit and a timing control circuit. The controller 1120-1 may receive an image signal from the main processor 1110, convert the data format of the image signal to match the interface specifications of the display device 1, and output image data. The controller 1120-1 may output various control signals necessary to drive the display device 1.

The secondary processor 1120 may further include a data conversion circuit 1120-2, a gamma correction circuit 1120-3, and a rendering circuit 1120-4. The data conversion circuit 1120-2 may receive image data from the controller 1120-1 and may perform compensation on the image data such that an image is displayed at a desired brightness according to user settings and the characteristics of the electronic device 1000 or may convert the image data to reduce power consumption or compensate for an afterimage. The gamma correction circuit 1120-3 may convert image data or a gamma reference voltage such that an image displayed on the electronic device 1000 has desired gamma characteristics. The rendering circuit 1120-4 may receive image data from the controller 1120-1 and may render the image data taking into account a pixel arrangement of the display panel 10 applied to the electronic device 1000. At least one selected from the group consisting of the data conversion circuit 1120-2, the gamma correction circuit 1120-3, and the rendering circuit 1120-4 may be integrated into another component (e.g., the main processor 1110 or the controller 1120-1). At least one selected from the group consisting of the data conversion circuit 1120-2, the gamma correction circuit 1120-3, and the rendering circuit 1120-4 may be integrated into a data driver DD described below.

The memory 1200 may store various data used by at least one component (e.g., the processor 1100 or the sensor module 1610) of the electronic device 1000 and may store input data or output data for commands related to the various data. The memory 1200 may include at least one of the volatile memory 1210 and the non-volatile memory 1220.

The input module 1300 may receive a command or data to be used in a component (e.g., the processor 1100, the sensor module 1610, or the audio output module 1630) of the electronic device 1000 from the outside (e.g., a user or the external electronic device 1020) of the electronic device 1000.

The input module 1300 may include a first input module 1310, into which a command or data from a user is input, and a second input module 1320, into which a command or data from the external electronic device 1020 is input. The first input module 1310 may include a microphone, a mouse, a keyboard, a key (e.g., a button), or a pen (e.g., a passive pen or an active pen). The second input module 1320 may support a designated protocol that may carry out wired or wireless connection with the external electronic device 1020. According to an embodiment, the second input module 1320 may include a high definition multimedia interface (HDMI), a universal serial bus (USB) interface, a secure digital (SD) card interface, or an audio interface. The second input module 1320 may include a connector, for example, an HDMI connector, a USB connector, an SD card connector, or an audio connector (e.g., a headphone connector), which may physically connect the electronic device 1000 to the external electronic device 1020.

The display device 1 may visually provide information to the user. The display device 1 may include the display panel 10, a scan driver GP, and the data driver DD. The display device 1 may further include a window, a chassis, and a bracket to protect the display panel 10.

The display panel 10 may further include a light emission driver. The light emission driver may output a light emission control signal to the display panel 10 in response to a control signal received from the controller 1120-1. The light emission driver may be formed separately from the scan driver GP or may be integrated into the scan driver GP.

The scan driver GP may receive a control signal from the controller 1120-1 and outputs scan signals to the display panel 10 in response to the control signal. For example, a control signal generated by the controller 1120-1 and transmitted to the scan driver GP may correspond to a scan input signal for controlling the scan driver GP. The scan input signal may correspond to an input signal applied to switching elements included in the stages of the scan driver.

The data driver DD may receive a control signal from the controller 1120-1, convert image data into analog voltages (e.g., data voltages) in response to the control signal, and then output the data voltages to the display panel 10. For example, a control signal generated by the controller 1120-1 and transmitted to the data driver DD may correspond to a data input signal for controlling the data driver DD.

The data driver (DD) may be integrated into another component (e.g., the controller 1120-1). The functions of the interface conversion circuit and the timing control circuit of the controller 1120-1 may be integrated into the data driver DD.

The controller 1120-1 may generate a clock signal required to drive the scan driver GP. Each stage of the scan driver GP may operate based on a clock signal corresponding to the stage.

The scan driver GP may generate a scan signal based on a scan input signal, a clock signal, and a scan input voltage. The scan signal may be transmitted to a pixel circuit, and a TFT included in the pixel circuit may be driven based on the scan signal. The scan signal may be transmitted to a gate of the pixel circuit.

The display device 1 may further include a light emission driver and a voltage generation circuit. The voltage generation circuit may output various voltages required to drive the display panel 10.

The power module 1500 may supply power to components of the electronic device 1000. The power module 1500 may generate a gate driving voltage (e.g., a gate high voltage or a gate low voltage) required to drive the scan driver GP.

For example, the power module 1500 may refer to a power generation unit, a power supply, or the like. For example, the power module 1500 may include a battery that charges a power supply voltage. The battery may include a non-rechargeable primary battery, a rechargeable secondary battery, or a fuel cell.

For example, the power module 1500 may include a power management integrated circuit (PMIC). The PMIC may provide optimized power to each of the modules described above and modules described below.

For example, the power module 1500 may include a wireless power transceiver electrically connected to a battery. The wireless power transceiver may include a plurality of coil-shaped antenna radiators.

The electronic device 1000 may further include the built-in module 1600 and the external module 1700. The built-in module 1600 may include the sensor module 1610, the antenna module 1620, and the audio output module 1630. The external module 1700 may include the camera module 1710, a light module 1720, and the communication module 1730.

The sensor module 1610 may detect an input by a user's body or an input by a pen of the first input module 1310 and may generate an electrical signal or a data value, which corresponds to the input. The sensor module 1610 may include at least one selected from the group consisting of the fingerprint sensor 1610-1, the input sensor 1610-2, and a digitizer 1610-3.

The fingerprint sensor 1610-1 may generate a data value corresponding to a user's fingerprint. The fingerprint sensor 1610-1 may include either an optical fingerprint sensor or a capacitive fingerprint sensor.

The input sensor 1610-2 may generate a data value corresponding to coordinate information of an input by a user's body or an input by a pen. The input sensor 1610-2 may generate a data value corresponding to a variance in electrostatic capacitance due to an input. The input sensor 1610-2 may detect an input by a passive pen or may exchange data with an active pen.

The input sensor 1610-2 may also measure a biosignal, such as blood pressure, moisture, or body fat. For example, when a user touches a sensor layer or a sensing panel with a part of his or her body and does not move for a certain period of time, the input sensor 1610-2 may detect a biosignal based on a change in an electric field caused by the part of his or her body and may output information desired by the user to the display device 1.

The digitizer 1610-3 may generate a data value corresponding to coordinate information of an input by a pen. The digitizer 1610-3 may generate a data value based on an electromagnetic variance in the input. The digitizer 1610-3 may detect an input by a passive pen or exchange data with an active pen.

At least one selected from the group consisting of the fingerprint sensor 1610-1, the input sensor 1610-2, and the digitizer 1610-3 may be implemented as a sensor layer formed on the display panel 10 through a continuous process. The fingerprint sensor 1610-1, the input sensor 1610-2, and the digitizer 1610-3 may be arranged above the display panel 10, and any one of the fingerprint sensor 1610-1, the input sensor 1610-2, and the digitizer 1610-3, for example, the digitizer 1610-3, may be arranged below the display panel 10.

At least two of the fingerprint sensor 1610-1, the input sensor 1610-2, and the digitizer 1610-3 may be formed to be integrated into a single sensing panel through the same process. When they are integrated into a single sensing panel, the sensing panel may be arranged between the display panel 10 and a window above the display panel 10. According to an embodiment, the sensing panel may be arranged on a window. The location of the sensing panel is not particularly limited.

At least one selected from the group consisting of the fingerprint sensor 1610-1, the input sensor 1610-2, and the digitizer 1610-3 may be embedded in the display panel 10. In other words, at least one selected from the group consisting of the fingerprint sensor 1610-1, the input sensor 1610-2, and the digitizer 1610-3 may be simultaneously formed in a process of forming elements (e.g., a light-emitting device, a transistor, etc.) included in the display panel 10.

In addition, the sensor module 1610 may generate an electrical signal or a data value, which corresponds to an internal or external state of the electronic device 1000. The sensor module 1610 may further include, for example, a gesture sensor, a gyro sensor, a pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 1620 may include at least one antenna for transmitting signals or power to or receiving signals or power from the outside. According to an embodiment, the communication module 1730 may transmit a signal to an external electronic device or receive a signal from an external electronic device through an antenna suitable for a communication method. The antenna pattern of the antenna module 1620 may be integrated into one component (e.g., the display panel 10) of the display device 1 or the input sensor 1610-2.

The audio output module 1630 may correspond to a device that outputs audio signals to the outside of the electronic device 1000 and may include, for example, a speaker used for a general purpose, such as multimedia playback or recording playback, and a receiver used exclusively for receiving phone calls. According to an embodiment, the receiver may be formed integrally with or separately from the speaker. The sound output pattern of the sound output module 1630 may be integrated into the display device 1.

The camera module 1710 may capture still images and moving images. According to an embodiment, the camera module 1710 may include at least one lens, an image sensor, or an image signal processor. The camera module 1710 may further include an infrared camera capable of measuring the presence or absence of a user, the user's location, the user's line of sight, etc.

The light module 1720 may provide light. The light module 1720 may include a light-emitting diode or a xenon lamp. The light module 1720 may operate independently or in association with the camera module 1710.

The communication module 1730 may establish a wired or wireless communication channel between the electronic device 1000 and the external electronic device 1020 and support communication through the established communication channel. The communication module 1730 may include one or both of a wireless communication module, such as a cellular communication module, a short-range wireless communication module, or a global navigation satellite system (GNSS) communication module, and a wired communication module, such as a local area network (LAN) communication module or a power line communication module. The communication module 1730 may communicate with the external electronic device 1020 via a short-range communication network, such as Bluetooth, Wi-Fi direct, or infrared data association (IrDA), or a long-range communication network, such as a cellular network, the Internet, or a computer network (e.g., a LAN or a wide area network (WAN)). The various types of communication modules 1730 described above may be implemented in a single chip or separate chips.

The input module 1300, the sensor module 1610, and the camera module 1710 may be used to control the operation of the display device 1 in association with the processor 1100.

The processor 1100 may output a command or data to the display device 1, the audio output module 1630, the camera module 1710, or the light module 1720, based on input data received from the input module 1300. For example, the processor 1100 may generate image data in response to input data applied through a mouse or an active pen and output the image data to the display device 1 or may generate command data in response to the input data and output the command data to the camera module 1710 or the light module 1720. When no input data is received from the input module 1300 for a certain period of time, the processor 1100 may switch the operation mode of the electronic device 1000 to a low-power mode or a sleep mode to reduce power consumption of the electronic device 1000.

The processor 1100 may outputs a command or data to the display device 1, the audio output module 1630, the camera module 1710, or the light module 1720, based on sensing data received from the sensor module 1610. For example, the processor 1100 may compare authentication data applied by the fingerprint sensor 1610-1 with authentication data stored in the memory 1200 and then execute an application according to a result of the comparison. The processor 1100 may execute a command or output image data to the display device 1, based on sensing data detected by the input sensor 1610-2 or the digitizer 1610-3. When a temperature sensor is included in the sensor module 1610, the processor 1100 may receive temperature data on a measured temperature from the sensor module 1610 and perform brightness correction or the like on image data, based on the temperature data.

The processor 1100 may receive measurement data regarding the presence or absence of a user, the user's location, the user's line of sight, or the like from the camera module 1710. The processor 1100 may further perform brightness correction or the like on the image data, based on the measurement data. For example, the processor 1100 may determine the presence or absence of a user through an input from the camera module 1710 and may output image data of which the brightness has been corrected by the data conversion circuit 1120-2 or the gamma correction circuit 1120-3, to the display device 1.

Some of the components described above may be connected to each other and may exchange signals (e.g., commands or data) with each other via a communication method between peripheral devices, for example, a bus method, a general purpose input/output (GPIO) method, a serial peripheral interface (SPI) method, a mobile industry processor interface (MIPI) method, or an ultra path interconnect (UPI) link method. The processor 1100 may communicate with the display device 1 through a mutually agreed interface, for example, any one of the communication methods mentioned above. However, the communication method used by the processor 1100 is not limited thereto.

According to various embodiments disclosed herein, the electronic device 1000 may be any of devices of various types. The electronic device 1000 may include, for example, at least one selected from the group consisting of a portable communication device (e.g., a smartphone), a computer device, a portable multimedia device, a portable medical device, a camera, a wearable device, and a home appliance. The electronic device 1000 according to the embodiments of this document is not limited to the devices mentioned above.

In an embodiment, the display device 1 may include the display panel 10 and the scan driver GP. The controller 1120-1 may generate a scan input signal required to drive the scan driver GP. The power module 1500 may generate a scan input voltage required to drive the scan driver GP under control by the processor 1100 or the controller 1120-1. For example, the scan input voltage may correspond to a gate driving voltage.

The display panel 10 may be divided into the display area DA, in which a pixel circuit is arranged, and the peripheral area PA around the display area DA. As described above, an area, in which an image is displayed, may be the display area DA, and an area, which is outside the display area DA and in which an image is not displayed, may be the peripheral area PA.

The scan driver GP may be arranged in the peripheral area PA and may receive a scan input signal from the controller 1120-1 and a scan input voltage from the power module 1500. The scan driver GP may generate or output a scan signal based on the scan input signal and/or the scan input voltage. The scan signal may be transmitted from the scan driver GP to the pixel circuit.

In an embodiment, the scan driver GP may include at least one capacitor. The capacitor may include one electrode and another opposite electrode. For example, one electrode may correspond to a signal line that carries at least one of a scan input signal and a scan input voltage. For example, one electrode may correspond to at least a portion of a signal line that carries at least one of a scan input signal and a scan input voltage. For example, a signal line may include a wire through which a scan input voltage is transmitted.

For example, the other electrode may overlap one electrode. The other electrode may overlap a signal line carrying at least one of a scan input signal and a scan input voltage. For example, the other electrode may overlap at least a portion of a signal line carrying at least one of a scan input signal and a scan input voltage.

In an embodiment, the peripheral area PA may include a wiring arrangement area, in which wirings are arranged, and a circuit arrangement area, in which at least one transistor is arranged, between the display area DA and the wiring arrangement area. For example, at least one capacitor may be arranged in the wiring arrangement area.

As described above, according to an embodiment of the present disclosure, a display device, a method of manufacturing the display device, and an electronic device including the display device may provide a display device and a method for manufacturing the display device, which have improved stability and optical characteristics.

According to the present disclosure, a display device having improved stability and optical characteristics, a method of manufacturing the display device, and an electronic device including the display device may be provided.

However, these effects are exemplary, and the effects of the present disclosure are not limited thereto.

Each of the embodiments described above can be implemented independently, but it should be noted that the structure of each embodiment can be applied in combination to other embodiments.

Although the present disclosure has been described with reference to the embodiments shown in the drawings, these are merely exemplary, and those skilled in the art will understand that various modifications can be made in the embodiments and equivalent other embodiments can be inferred therefrom. Therefore, the technical scope of the present disclosure should be defined by the spirit of the appended claims.

The particular implementations described herein are illustrative examples of embodiments and are not intended to otherwise limit the scope of the embodiments in any way. Moreover, no component is essential to the practice of embodiments unless the component is specifically described as “essential” or “critical.”

The use of the terms "a", and "an" and "the" and similar referents in the context describing embodiments (especially in the context of the following claims) are to be construed to cover both the singular and the plural. Furthermore, recitation f ranges of values herein are merely intended to serve as a shorthand method of referring individual to each separate value falling within the range, unless otherwise indicated herein, and each separate value is incorporated into the specification as if it were individually recited herein. Also, the operations of all methods described herein can be performed in any suitable order unless otherwise indicated herein or otherwise clearly contradicted by context. Embodiments are not limited to the described order of the operations. The use of any and all examples or exemplary language provided herein is intended merely to elaborate embodiments and does not pose a limitation on the scope of embodiments unless otherwise claimed. Numerous modifications and adaptations will be readily apparent to one of ordinary skill in the art without departing from the spirit and scope of the appended claims or their equivalents.

What is claimed is:

1. An electronic device comprising:
a display device divided into a display area, in which a pixel circuit is arranged, and a peripheral area, which is outside the display area and includes a pad area,
wherein the display device includes:
a display panel including the display area and the peripheral area surrounding the display area;
a protective film layer on the display panel;
a polarizing layer on the protective film layer;
an adhesive layer including a first adhesive layer between the display panel and the protective film layer and a second adhesive layer between the protective film layer and the polarizing layer;
a light-shielding member on at least one of opposite surfaces of the protective film layer; and
a housing covering at least a portion of an outer perimeter of the display panel.

2. The electronic device of claim 1, wherein a storage modulus of the first adhesive layer is greater than a storage modulus of the second adhesive layer.

3. The electronic device of claim 1, wherein the housing overlaps at least a portion of each of a side surface and a top surface of the second adhesive layer.

4. The electronic device of claim 1, wherein the housing is in contact with at least a portion of a side surface of the polarizing layer.

5. The electronic device of claim 1, further comprising a sealing portion between the display panel and the housing.

6. The electronic device of claim 1, wherein the protective film layer includes an organic material.

7. The electronic device of claim 1, wherein the display panel includes a substrate, a pixel layer on the substrate, and an encapsulation member on the pixel layer.

8. The electronic device of claim 1, wherein the polarizing layer includes a hard coating layer in an outermost part of the display device.

9. A display device comprising:
a display panel including a display area and a peripheral area surrounding the display area;
a protective film layer on the display panel;
a polarizing layer on the protective film layer;
an adhesive layer including a first adhesive layer between the display panel and the protective film layer and a second adhesive layer between the protective film layer and the polarizing layer; and
a light-shielding member on at least one of opposite surfaces of the protective film layer.

10. The display device of claim 9, wherein the light-shielding member is arranged between the protective film layer and the polarizing layer and between the protective film layer and the display panel.

11. The display device of claim 10, wherein the light-shielding member is arranged inside the adhesive layer.

12. The display device of claim 10, wherein the light-shielding member is arranged inside the protective film layer.

13. The display device of claim 9, wherein the light-shielding member has a thickness less than half a thickness of the first adhesive layer or the second adhesive layer.

14. The display device of claim 9, wherein the light-shielding member overlaps the peripheral area.

15. The display device of claim 9, wherein the first adhesive layer and the second adhesive layer have different storage moduli from each other.

16. The display device of claim 14, wherein a storage modulus of the first adhesive layer is greater than a storage modulus of the second adhesive layer.

17. The display device of claim 16, wherein, when the polarizing layer shrinks, a surface of the second adhesive layer in contact with the polarizing layer shrinks in a shrinkage direction of the polarizing layer.

18. The display device of claim 9, wherein, as viewed in a direction perpendicular to the display panel, the polarizing layer is spaced apart inward from an edge of the protective film layer.

19. The display device of claim 9, wherein
the display panel further includes a substrate, a pixel layer on the substrate, and an encapsulation member on the pixel layer.

20. The display device of claim 9, wherein
the polarizing layer includes a hard coating layer in an outermost part of the display device.
